(19) United States
(12) Patent Application Publication
(10) Pub. No.: US 2024/0380393 A1
(43) Pub. Date: Nov. 14, 2024

(54) Bipolar Pulsed High Voltage Electric Field Treatment

(71) Applicant: EHT Ventures LLC, Seattle, WA (US)

(72) Inventors: Alex Henson, Seattle, WA (US); Kevin Muggli, Mountlake Terrace, WA (US); Timothy Ziemba, Bainbridge Island, WA (US); Kenneth Miller, Seattle, WA (US)

(21) Appl. No.: 18/782,013

(22) Filed: Jul. 23, 2024

Related U.S. Application Data
(63) Continuation-in-part of application No. 18/512,002, filed on Nov. 16, 2023.
Application No. 18/512,002 is a continuation of application No. 17/853,891, filed on Jun. 29, 2022, now Pat. No. 11,824,542.

(51) Int. Cl. H03K 3/57; H02M 3/07

(52) U.S. Cl. CPC H03K 3/57; H02M 3/07

(57) ABSTRACT

Bipolar high voltage bipolar pulsing treatment systems, devices, and methods are disclosed that include electrodes for ablation or electroporation and power supplies for supplying bipolar high voltage pulses to the electrode. The power supply includes a DC Source, an energy storage capacitor coupled with the DC source, a first high voltage switch electrically coupled with the DC source and the energy storage capacitor, and a first diode arranged across arranged across the first high voltage switch. In some cases, the power supply can produce high voltage bipolar pulses with a positive high voltage pulse greater than about 200 V followed by a negative high voltage pulse less than about −200 V with a positive to negative dwell period between the positive high voltage pulse and the negative high voltage pulse.

### CROSS-REFERENCE TO RELATED APPLICATIONS

This application is a continuation-in-part of U.S. patent application Ser. No. 18/512,002, filed Nov. 16, 2023, which is a continuation of U.S. patent application Ser. No. 17/853,891, filed on Jun. 29, 2022, now U.S. Pat. No. 11,824,542, the discourses of which are incorporated in their entirety by reference herein.

### BACKGROUND

Tissue ablation can be used to address a variety of medical issues. For example, for cardiac applications specialized multielectrode catheters have been used to deliver electroporation to the ostium of the pulmonary veins within the left atrium. In other examples, chronic diseases (e.g., obesity and diabetes) have been treated through duodenal resurfacing. It is believed that removing most of the mucosal cells from the section of the large intestine nearest the stomach may allow a rejuvenated mucosal layer to be regenerated, thereby restoring healthy signaling. Applying thermal energy to the duodenum can result in excessive heating that damages additional layers of the duodenum, such as the muscularis. Accordingly, there is a need for improved ablation treatment methods, systems, and devices that can limit ablation to desired tissues and/or locations.

### SUMMARY

Bipolar high voltage treatment methods, devices, and systems are disclosed that include an electrode for ablation or electroporation and a power supply. In some cases, the power supply can provide bipolar high voltage pulses to the electrode. The power supply can include a DC Source, an energy storage capacitor coupled with the DC source, a first high voltage switch electrically coupled with the DC source and the energy storage capacitor, and a first diode arranged across arranged across the first high voltage switch. In some cases, the power supply can be adapted to produce high voltage bipolar pulses with a positive high voltage pulse greater than about 200 V followed by a negative high voltage pulse less than about −200 V, a positive high voltage pulse greater than about 500 V followed by a negative high voltage pulse less than about −500 V, or a positive high voltage pulse greater than about 2,000 V followed by a negative high voltage pulse less than about −2,000 V. In some cases, the methods, devices, and systems disclosed herein can apply high voltage pulses to an electrode for ablation treatment with a pulse repetition frequency greater than about 10 kHz. In some cases, the methods, devices, and systems disclosed herein can deliver a pulsed waveform to the electrode to generate an electric field to treat tissue.

A bipolar high voltage bipolar pulsing power supply, for example, is disclosed that can produce high voltage bipolar pulses with a positive high voltage pulse greater than about 2 kV followed by a negative high voltage pulse less than about −2 kV with a positive to negative dwell period between the positive high voltage pulse and the negative high voltage pulse. A high voltage bipolar pulsing power supply, for example, can reproduce high voltage pulses with a high pulse repetition frequency greater than about 10 kHz.

A high voltage bipolar pulsing power supply, for example, is disclosed that includes a DC source; an energy storage capacitor coupled with the DC source; a first high voltage switch electrically coupled with the DC source and the energy storage capacitor; a first diode arranged across the first high voltage switch; a second high voltage switch electrically coupled with the DC source and the energy storage capacitor; a second diode arranged across the second high voltage switch; a third high voltage switch arranged in series between the first high voltage switch and ground; a third diode arranged across the third high voltage switch; a fourth high voltage switch arranged in series between the second high voltage switch and ground; a fourth diode arranged across the fourth high voltage switch; and an output having a first lead electrically coupled between first high voltage switch and the third high voltage switch and the second lead electrically coupled between second high voltage switch and the fourth high voltage switch.

In some examples, the first high voltage switch, the second high voltage switch, the third high voltage switch, and/or the fourth high voltage switch each have a capacitance less than about 10 nF.

In some examples, the first high voltage switch includes a first plurality of solid-state switches arranged in parallel, the second high voltage switch includes a second plurality of solid-state switches arranged in parallel, the third high voltage switch includes a third plurality of solid-state switches arranged in parallel, and/or the fourth high voltage switch include a fourth plurality of solid state switches arranged in parallel.

In some examples, the first high voltage switch, the second high voltage switch, the third high voltage switch, and/or the fourth high voltage switch each include a switch selected from the group consisting of an IGBT, a MOSFET, a SiC MOSFET, a SiC junction transistor, a FET, a SiC switch, a GaN switch, and a photoconductive switch.

In some examples, the circuit comprising both the DC source and the energy storage capacitor has an inductance less than about 10 nH.

In some examples, the circuit comprising both the first high voltage bipolar pulsing power supply and the second high voltage switch has an inductance less than about 10 nH.

In some examples, the first lead of the output is coupled with a first lead of an electrode and the second lead of the output is coupled with a second lead of the electrode.

The high voltage bipolar pulsing power supply, for example, can also include a first tail sweeper switch and a first tail sweeper resistor arranged in series across the first high voltage switch; a second tail sweeper switch and a second tail sweeper resistor arranged in series across the first high voltage switch; a third tail sweeper switch and a third tail sweeper resistor arranged in series across the first high voltage switch; and a fourth tail sweeper switch and a fourth tail sweeper resistor arranged in series across the first high voltage switch.

A high voltage, multilevel, bipolar pulsing power supply, for example, is disclosed that includes: a first DC source; a first energy storage capacitor coupled with the first DC source; a first diode having an anode and a cathode, the anode electrically coupled with the first DC source and the first energy storage capacitor; a first high voltage switch electrically coupled with the cathode of the first diode; a first diode arranged across the first high voltage switch; a second high voltage switch electrically coupled with the cathode of the first diode; a second diode arranged across the second high voltage switch; a third high voltage switch arranged in series between the first high voltage switch and ground; a third diode arranged across the third high voltage switch; a fourth high voltage switch arranged in series between the second high voltage switch and ground; a fourth diode arranged across the fourth high voltage switch; a second DC source; a second energy storage capacitor coupled with the second DC source; a fifth high voltage switch electrically coupled with the second DC source and the second energy storage capacitor; a fifth diode arranged across the fifth high voltage switch; a sixth high voltage switch electrically coupled with the cathode of the second DC source and the second energy storage capacitor; a sixth diode arranged across the sixth high voltage switch; and an output having a first lead electrically coupled between first high voltage switch and the third high voltage switch and the second lead electrically coupled between second high voltage switch and the fourth high voltage switch.

In some examples, the second DC source produces a voltage greater than the first DC source.

In some examples, the first high voltage switch, the fourth high voltage switch, and the fifth high voltage switch are closed to produce a voltage at the output equal to a voltage of the second DC source; the second high voltage switch, the third high voltage switch, and the sixth high voltage switch are closed to produce a voltage at the output equal to a negative voltage of the second DC source; the first high voltage switch and the fourth high voltage switch are closed to produce a voltage at the output equal to a voltage of the first DC source; and the second high voltage switch and the third high voltage switch are closed to produce a voltage at the output equal to a negative voltage of the first DC source.

In some examples, the first high voltage switch, the second high voltage switch, the third high voltage switch, the fourth high voltage switch, the fifth high voltage switch, and the sixth high voltage switch each have a capacitance less than about 500 pF.

The high voltage bipolar pulsing power supply, for example, may also include a first tail sweeper switch and a first tail sweeper resistor arranged in series across the first high voltage switch; a second tail sweeper switch and a second tail sweeper resistor arranged in series across the first high voltage switch; a third tail sweeper switch and a third tail sweeper resistor arranged in series across the first high voltage switch; a fourth tail sweeper switch and a fourth tail sweeper resistor arranged in series across the first high voltage switch; a fifth tail sweeper switch and a fifth tail sweeper resistor arranged in series across the fifth high voltage switch; and a sixth tail sweeper switch and a sixth tail sweeper resistor arranged in series across the sixth high voltage switch.

A high voltage, multilevel, bipolar pulsing power supply, for example, is disclosed that includes: a DC source; an energy storage capacitor coupled with the DC source; a diode having an anode and a cathode, the anode electrically coupled with the DC source and the energy storage capacitor; a first high voltage switch electrically coupled with the cathode of the diode; a first diode arranged across the first high voltage switch; a first tail sweeper switch and a first tail sweeper resistor arranged in series across the first high voltage switch; a second high voltage switch electrically coupled with the cathode of the diode; a second diode arranged across the second high voltage switch; a second tail sweeper switch and a second tail sweeper resistor arranged in series across the first high voltage switch; a third high voltage switch arranged in series between the first high voltage switch and ground; a third diode arranged across the third high voltage switch; a third tail sweeper switch and a third tail sweeper resistor arranged in series across the first high voltage switch; a fourth high voltage switch arranged in series between the second high voltage switch and ground; a fourth diode arranged across the fourth high voltage switch; a fourth tail sweeper switch and a fourth tail sweeper resistor arranged in series across the first high voltage switch; and an output having a first lead electrically coupled between first high voltage switch and the third high voltage switch and the second lead electrically coupled between second high voltage switch and the fourth high voltage switch.

In some examples, the first tail sweeper switch is closed prior to the first high voltage switch being closed; the second tail sweeper switch is closed prior to the second high voltage switch being closed; the third tail sweeper switch is closed prior to the third high voltage switch being closed; and the fourth tail sweeper switch is closed prior to the fourth high voltage switch being closed.

In some examples, the first high voltage switch, the second high voltage switch, the third high voltage switch, and the fourth high voltage switch each include a switch selected from the group consisting of an IGBT, a MOSFET, a SiC MOSFET, a SiC junction transistor, a FET, a SiC switch, a GaN switch, and a photoconductive switch.

In some examples, the first tail sweeper switch, the second tail sweeper switch, the third tail sweeper switch, and the fourth tail sweeper switch each include a switch selected from the group consisting of an IGBT, a MOSFET, a SiC MOSFET, a SiC junction transistor, a FET, a SiC switch, a GaN switch, and a photoconductive switch.

In some examples, the circuit between the diode and both the DC source and the energy storage capacitor has an inductance less than about 10 nH.

In some examples, the circuit between the diode and the first high voltage bipolar pulsing power supply and the second high voltage switch has an inductance less than about 10 nH.

In some examples, the first lead of the output is coupled with a first lead of an electrode and the second lead of the output is coupled with a second lead of the electrode

Bipolar high voltage treatment devices, systems, and methods can include an apparatus having any suitable configuration. Bipolar high voltage treatment systems, devices, and methods can, for example, include a tissue ablation catheter that includes one or more electrodes for ablation or electroporation. In some cases, devices and systems provided herein can include an elongated body (e.g., a catheter) for delivery to a treatment location, an expandable member that includes at least one electrode for ablation or electroporation, and a power supply for supplying a pulsed waveform to the electrode to treat tissue. In some cases, the tissue being treated in methods provided herein can include cardiac tissue, gastrointestinal tissues, kidney tissue, or nervous tissue. In some cases, an expandable member can include multiple configurations (e.g., a compressed configuration and an expanded configuration). In some cases, an expanded configuration can be adapted to dilate tissue in or adjacent to a treatment region. In some cases, devices, systems, and methods provided herein can include a fluid opening in an expandable member, which can be used to apply fluid to a treatment location and/or to provide suction to a treatment location. In some examples, a catheter can include an insulator between inner and outer electrodes. In some examples, arrangements of electrodes for electroporation on a catheter can generate novel electric field shapes that may improve ablation targeting and/or consistency.

Bipolar high voltage treatment systems, devices, and methods can include a controller to control the pulses delivered to one or more electrodes for ablation or electroporation. In some examples, a controller can be used to control the pulses delivered to one or more electrodes for electroporation on a catheter to generate novel electric field shapes that may improve ablation targeting and/or consistency. In some cases, systems and devices provided herein can include temperature feedback and/or visualization of procedures.

Bipolar high voltage treatment devices, systems, and methods provided herein can, in some cases, treat duodenal tissue of a patient to treat diabetes. In some cases, a device or system provided herein can include a first elongate body having a lumen, a second elongate body at least partially positioned within the lumen, and an expandable member rolled about the second elongate body. The expandable member may include an inner end coupled to the second elongate body, an outer end coupled to the first elongate body, and an electrode array. In some cases, the expandable member may include a plurality of turns about the second elongate body. In some cases, a connector may couple the first elongate body to the outer end of the expandable member. In some cases, the second elongate body may be configured to rotate relative to the first elongate body to transition the expandable member between a rolled configuration and an unrolled configuration. In some cases, the expandable member may include a lumen of at least 10 mm in diameter in the unrolled configuration.

In some cases, devices, systems, and methods can monitor a temperature of tissue in or surrounding a treatment location and control the delivery of a pulse waveform to a treatment location based on a temperature of such tissue. In some cases, an electrode for ablation or electroporation may be configured to generate a therapeutic electric field at a first tissue depth of about 1 mm and a non-therapeutic electric field at a second tissue depth of at least about 1.5 mm. In some cases, an expandable member or a device or system provided herein may include a temperature sensor having a serpentine shape. In some cases, the expandable member may define one or more openings through the expandable member. In some cases, one or more electrodes may be configured to generate a therapeutic electric field that treats a predetermined set of cell types and not muscularis tissue. In some cases, the electrode array may be configured to generate a therapeutic electric field that treats cells but leaves intact tissue scaffolding.

Electrodes for ablation or electroporation in devices, systems, and methods provided herein can have any suitable configuration. In some cases, a plurality of elongated electrodes can be included on an elongate body (e.g., a catheter) for delivery to a treatment location. In some cases, elongate electrodes may have a ratio of a center-to-center distance between proximate electrodes to a width of the electrodes between about 2.3:1 and about 3.3:1. In some cases, the plurality of elongate electrodes can have a center-to-center distance between proximate electrodes of less than about 5 mm.

In some cases, devices, systems, or methods provided herein can be configured to provide a pulsed or modulated electric field waveform comprising a frequency between about 250 kHz and about 950 kHz, a pulse width between about 0.5 μs and about 4 μs, a voltage applied by the electrode array of between about 100 V and about 2 kV, and a current density between about 0.6 A and about 100 A from the electrode array per square centimeter of tissue.

Tissue contacting surfaces of devices and systems provided herein can be formed of any suitable material. In some cases, devices and systems provided herein can include a tissue contacting layer. In some cases, the conductivity of the tissue contact layer may be between about 0.03 S/m and about 0.9 S/m. For example, the conductivity of the tissue contact layer may be between about 0.03 S/m and about 0.6 S/m or between about 0.03 S/m and about 0.3 S/m. In some cases, the tissue contact layer may include a thickness of between about 10% and about 20% of a width of the electrode. In some cases, at least one of the electrodes may include a semi-elliptical cross-sectional shape. In some cases, a ratio of a height of an electrode to a width of an electrode is between about 1:4 and about 1:8. In some cases, the proximate electrodes may be spaced apart by a weighted average distance of between about 0.3 mm and about 6 mm. In some cases, a hydrophilic layer may be disposed over the plurality of electrodes. In some cases, a conductive layer may be disposed over the plurality of electrodes. The conductive layer may include one or more of a polymer and conductive media comprising graphite, silver, metals, and the like. In some cases, the conductive layer may be a coating. In some cases, a surface area of the plurality of electrodes may include between about 20% and about 45% of a surface area of the expandable member in a predetermined configuration (e.g., expanded configuration).

In some cases, the expandable member may be concentrically coupled to the elongate body. In some cases, the elongate body may be coupled to a sidewall of the expandable member. In some cases, a second expandable member may be coupled to the elongate body and disposed distal to the expandable member. In some cases, at least a proximal end and a distal end of the second expandable member may be transparent. In some cases, a second elongate body may be disposed within a lumen of the expandable member. In some cases, the plurality of electrodes includes a plurality of parallel elongate electrodes. In some cases, the plurality of electrodes may include a plurality of interdigitated electrodes.

In some cases, a system may include an elongate body and an expandable member coupled to the elongate body. The elongate body includes a lumen, a compressed configuration, and an expanded configuration. The expandable member includes an electrode array. The lumen of the expandable member may be configured to releasably couple to a visualization device. In some cases, the lumen defines a central longitudinal axis of the expandable member. In some cases, the expandable member may include the fluid opening. In some cases, the expandable member may include one or more fluid channels.

Also described herein are systems comprising an elongate body, an expandable member coupled to the elongate body comprising a compressed configuration and an expanded configuration. The expandable member may further include an electrode array comprising a plurality of electrodes, and a signal generator coupled to the electrode array. The signal generator may be configured to deliver a pulsed or modulated electric field waveform to the electrode array to generate a therapeutic electric field at a first tissue depth of about 1 mm and a non-therapeutic electric field at a second tissue depth of at least about 1.5 mm.

Also described herein are systems comprising an elongate body and an expandable member coupled to the elongate body and comprising a lumen, a compressed configuration, and an expanded configuration. The expandable member may include an electrode array. The lumen of the expandable member may be configured to releasably receive a visualization device.

In some cases, the lumen may define a central longitudinal axis of the expandable member. In some cases, the expandable member may include one or more openings extending through the expandable member. In some cases, the visualization device may be configured to suction tissue through the one or more openings at a pressure between about 10 mmHg and about 200 mmHg.

Also described herein are systems comprising an elongate body and an expandable member coupled to the elongate body and comprising a lumen, a compressed configuration, and an expanded configuration. The expandable member may include an electrode array. A visualization device may be configured to releasably couple to a lumen of the expandable member. In some cases, the visualization device includes a suction lumen. In some cases, the visualization device includes an irrigation lumen.

Also described here are methods of treating diabetes comprising advancing a pulsed electric field device into a duodenum of a patient. The pulsed electric field device may include an elongate body and an expandable member coupled to the elongate body. The expandable member may include an electrode array. A pulsed waveform may be delivered to the electrode array to generate a pulsed or modulated electric field thereby treating the duodenum.

In some cases, the electrode array may include a plurality of spaced apart electrodes forming parallel lines and/or an interdigitated configuration. In some of these variations, proximate parallel lines of the electrode array may be configured with alternating polarity. In some cases, the plurality of electrodes may include a plurality of interdigitated electrodes. In some cases, the pulsed or modulated electric field may spatially vary up to about 20% at a predetermined treatment distance from the electrode array.

In some cases, the expandable member may include a lumen therethrough and the method may further include advancing an endoscope through the lumen of the expandable member. In some cases, the endoscope may be retracted to view duodenal tissue proximal of the expandable member. In some cases, each of the plurality of electrodes may be an elongate electrode. In some cases, each of the plurality of electrodes may be a hemi-elliptical electrode. In some cases, a temperature at the expandable member during delivery of the pulsed waveform may be measured. In some cases, delivery of the pulse waveform may be inhibited based on the measured temperature. In some cases, the pulsed or modulated electric field may be a therapeutic electric field at a first tissue depth of about 1 mm and a non-therapeutic electric field at a second tissue depth of at least about 1.5 mm. In some cases, tissue may be suctioned to the expandable member at a pressure between about 10 mmHg and about 200 mm-lg. In some cases, fluid may be output between the pulsed electric field device and the duodenum from the expandable member.

Also described here are methods of treating diabetes comprising advancing a pulsed electric field device toward a first portion of a duodenum of a patient. The pulsed electric field device may include an expandable member comprising an electrode array. The expandable member may be transitioned into an expanded configuration. A first pulse waveform may be delivered to the electrode array to generate a first pulsed or modulated electric field thereby treating the first portion. The pulsed electric field device may be advanced toward a second portion of the duodenum. A second pulse waveform may be delivered to the electrode array to generate a second pulsed electric field thereby treating the second portion.

In some cases, the expandable member may include a temperature sensor. A temperature of the tissue may be measured using the temperature sensor. Pulse waveform delivery may be modulated (e.g., inhibited) based on one or more of the measured temperature and a rate of temperature change. In some cases, the expandable member may be unrolled to transition the expandable member into the expanded configuration. In some cases, the expandable member may include a lumen having a first diameter in the compressed configuration and a second diameter in the expanded configuration. The second diameter may be larger than the first diameter. A third elongate body may be advanced through the lumen in the expanded configuration.

In some cases, the expandable member may include a second expandable member disposed distal to the expandable member. The second expandable member may be inflated. In some cases, unrolling the expandable member includes unrolling one or more turns of the expandable member. In some cases, the first and second pulse waveforms include a frequency between about 250 kHz and about 950 kHz, a pulse width between about 0.5 μs and about 4 μs, a voltage applied by the electrode array of between about 100 V and about 2 kV, and a current density between about 0.6 A and about 100 A or between about 0.6 A and about 65 A from the electrode array per square centimeter of tissue. For example, the current density may be between about 0.6 A and about 13 A from the electrode array per square centimeter of tissue. In some cases, fluid may be output between the pulsed electric field device and the duodenum from the expandable member.

In some cases, one or more of the first pulsed or modulated electric field and second pulsed or modulated electric field may be a therapeutic electric field at a first tissue depth of about 1 mm and a non-therapeutic electric field at a second tissue depth of at least about 1.5 mm.

In some cases, tissue may be suctioned to the expandable member during one or more of the delivery of the first pulse waveform and the second pulsed waveform.

Also described here are methods of treating diabetes comprising advancing a pulsed electric field device into a duodenum of a patient. The pulsed electric field device may include a first elongate body, a second elongate body positioned within the first elongate body, and an expandable member rolled about the second elongate body. The expandable member may include an electrode array. The second elongate body may rotate relative to the first elongate body to unroll the expandable member and contact duodenal tissue with the electrode array. A pulse waveform may be delivered to the electrode array to generate a pulsed or modulated electric field thereby treating the duodenal tissue.

In some cases, a visualization device may be advanced through a lumen of the unrolled expandable member. In some cases, rotating the first elongate body unrolls one or more turns of the expandable member. In some cases, the expandable member includes a temperature sensor, and further includes measuring a temperature of the tissue using the temperature sensor. Pulse waveform delivery may be modulated based on the measured temperature.

In some cases, rotating the first elongate body may transition the expandable member into the expanded configuration. In some cases, the expandable member may include a lumen having a first diameter in the compressed configuration and a second diameter in the expanded configuration. The second diameter may be larger than the first diameter. A third elongate body may be advanced through the lumen in the expanded configuration. In some cases, the expandable member may include a second expandable member disposed distal to the expandable member. The second expandable member may be inflated. In some cases, the pulse waveform may include a frequency between about 250 kHz and about 950 kHz, a pulse width between about 0.5 μs and about 4 μs, a voltage applied by the electrode array of between about 100 V and about 2 kV, and a current density between about 0.6 A and about 100 A or between about 0.6 A and about 65 A from the electrode array per square centimeter of tissue. For example, the current density may be between about 0.6 A and about 13 A from the electrode array per square centimeter of tissue. In some cases, fluid may be output between the pulsed electric field device and the duodenum from the expandable member.

In some cases, the pulsed or modulated electric field may be a therapeutic electric field at a first tissue depth of about 1 mm and a non-therapeutic electric field at a second tissue depth of at least about 1.5 mm. In some cases, tissue may be suctioned to the expandable member during delivery of the pulse waveform.

Also described are methods of treating diabetes comprising advancing a pulsed electric field device to a distal portion of a duodenum of a patient. The pulsed electric field device may include an expandable member. The expandable member may include an electrode array and a temperature sensor. The expandable member may transition into an expanded configuration. A first pulse waveform may be delivered to the electrode array to generate a first pulsed or modulated electric field thereby treating the distal portion. A visual marker may be generated on the distal portion using a temperature sensor. The pulsed electric field device may be retracted to a portion of the duodenum proximal to the distal portion based on a position of the visual marker. A second pulse waveform may be delivered to the electrode array to generate a second pulsed or modulated electric field thereby treating the second portion.

In some cases, fluid may be output between the pulsed electric field device and the duodenum from the expandable member. In some cases, the visual marker may include one or more vertices. In some cases, a visual marker may be generated on the duodenum by increasing a temperature of mucosa tissue to about 49° C. for less than about 2.5 seconds. In some cases, the visual marker may be configured to visually fade after about one day.

Also described are devices comprising an elongate body and an expandable member coupled to the elongate body. The expandable member may be configured to transition to an expanded configuration. An electrode array may be coupled to the expandable member. The electrode array may include a substrate, a first elongate electrode, and a second elongate electrode parallel to and spaced apart from the first elongate electrode. In some cases, the first and second elongate electrodes may include an interdigitated configuration. A first tissue temperature sensor may be disposed on the substrate between the first and second elongate electrodes.

In some cases, the first sensor may include a temperature resolution of less than about 0.5° C. In some cases, the first sensor may include a thermal diffusion time constant of less than about 5 milliseconds.

In some cases, a second temperature sensor may be configured to generate a visual marker on tissue. In some of these variations, the second sensor may be disposed on the substrate along a perimeter of the first and second elongate electrodes. The second sensor may include a spiral or serpentine shape.

In some cases, the first sensor may include an insulator configured to sustain without dielectric breakdown a pulse waveform configured to generate a pulsed or modulated electric field for treating tissue. In some cases, the insulator may include a thickness of at least about 0.02 mm. In some cases, the first sensor may include a width of up to about 0.07 mm and a length of at least about 2 cm. In some cases, a distance between the first sensor and either the first or second elongate electrode may be at least about 0.2 mm. In some cases, the first sensor may extend substantially parallel to the first and second elongate electrodes. In some cases, the expandable member may include the fluid opening. In some cases, the expandable member may include one or more fluid channels.

Also described herein are methods of treating diabetes comprising advancing a pulsed electric field device into a duodenum of a patient. The pulsed electric field device may include an expandable member. The expandable member may include an electrode array and a temperature sensor. The expandable member may be transitioned into an expanded configuration. A pulse waveform may be delivered to the electrode array to generate a pulsed or modulated electric field thereby treating the duodenum. A temperature of duodenal tissue may be measured using a temperature sensor. In some cases, the fiducial generator is the temperature sensor. In some cases, a visual marker may be generated on the duodenal tissue using a fiducial generator. In some cases, the visual marker may be visualized. A treatment area may be identified based on the visual marker. In some cases, fluid may be output between the pulsed or modulated electric field device and the duodenum from the expandable member. In some cases, the pulsed or modulated electric field may be a therapeutic electric field at a first tissue depth of about 1 mm and a non-therapeutic electric field at a second tissue depth of at least about 1.5 mm. In some cases, tissue may be suctioned to the expandable member during the delivery of the pulse waveform.

Also described are systems comprising an elongate body, an expandable member coupled to the elongate body comprising a compressed configuration and an expanded configuration. The expandable member may further include an electrode array comprising a plurality of electrodes. A signal generator may be coupled to the electrode array. The signal generator may be configured to deliver a pulsed or modulated electric field waveform to the electrode array to generate an electric field that spatially varies up to about 20% at a predetermined treatment distance from the electrode array. In some cases, the electrode array may include a plurality of electrodes comprising a ratio of a center-to-center distance between proximate electrodes to a width of the electrodes between about 2.3:1 and about 3.3:1. In some cases, the plurality of elongate electrodes include a center-to-center distance between proximate electrodes of less than about 5 mm. In some cases, a surface area of the plurality of electrodes includes between about 4% and about 100% of a circumference of a duodenum. In some cases, a fluid source may be in fluid communication with the electrode array. In some cases, one or more of the plurality of electrodes may include the fluid opening. In some cases, one or more of the plurality of electrodes may include a fluid channel in fluid communication with the fluid opening. In some cases, the system may be configured to generate a therapeutic electric field at a first tissue depth of about 1 mm and a non-therapeutic electric field at a second tissue depth of at least about 1.5 mm.

Also described are devices comprising an elongate body and an electrode array coupled to the elongate body. The electrode array may include a plurality of electrodes and a fluid opening. In some cases, one or more of the plurality of electrodes includes a fluid channel. In some cases, one or more of the plurality of electrodes includes the fluid opening. In some of these variations, the fluid opening is disposed at an apex of one or more of the plurality of electrodes.

In some cases, the electrode array may include a substrate comprising a fluid opening. In some of these variations, the substrate may include one or more fluid channels. In some cases, a fluid source may be in fluid communication with the electrode array. In some cases, the expandable member may include a fluid opening. In some cases, the expandable member may include one or more fluid channels. In some cases, fluid may be output between the pulsed electric field device and the duodenum from the expandable member. In some cases, the plurality of elongate electrodes may include a center-to-center distance between proximate electrodes of less than about 5 mm. In some cases, the visual marker may be visualized. A treatment area may be identified based on the visual marker.

In some cases, a signal generator may be coupled to the electrode array, the signal generator configured to generate a pulse waveform comprising a frequency of about 500 kHz, a pulse width from about 0.5 μs to about 4 Its, a voltage applied by the electrode array of about 2500 V. and a current density from about 0.6 A to about 100 A from the electrode array per square centimeter of tissue. In some cases, a ratio of depth of the pulsed or modulated electric field to a depth of duodenal tissue treated may be between about 0.3 and about 0.5. In some cases, a ratio of dilated to undilated mucosa tissue of the duodenum may be between about 0.40 and about 0.60, and a ratio of dilated to undilated submucosa tissue of the duodenum may be between about 0.15 and about 0.35. In some cases, the expandable member may include one or more openings between proximate electrodes. In some cases, the one or more openings may be configured for one or more of fluid egress, fluid suction, and tissue suction. In some cases, the treated duodenum may be histologically indistinguishable from native tissue after about 30 days. In some cases, the pulsed or modulated electric field may be substantially uniform at a predetermined tissue treatment depth of from about 0.5 mm to about 1.5 mm.

In some cases, the signal generator may be configured to inhibit delivery of the pulse waveform based on a temperature. In some cases, the signal generator may be configured to resume delivery of the pulse waveform based on one or more of a predetermined time period and temperature. In some cases, the temperature may be a change in temperature of up to about 6° C. In some cases, the tissue temperature may be about 43° C. In some cases, the predetermined time period may be up to about 60 seconds. In some cases, the electrode array may include a height of between about 0.003 in and about 0.015 in, a distance between adjacent electrodes of between about 1.0 mm and about 1.4 mm, and a pad width of between about 0.5 mm and about 0.7 mm. In some cases, the electrode array may include a bipolar configuration. In some cases, electrodes of the electrode array may be spaced apart between about 0.5 mm and about 2 mm. In some cases, the pulse waveform may include a voltage between about 450 V and about 70) V. In some cases, the device may be configured to generate a therapeutic electric field at a first tissue depth of about 1 mm and a non-therapeutic electric field at a second tissue depth of at least about 1.5 mm. In some cases, the expandable member may include a temperature sensor comprising a serpentine shape. In some cases, the expandable member may include a temperature sensor disposed generally perpendicular to the electrode array. In some cases, the fiducial generator may be configured to generate visual marker on tissue comprising one or more vertices. In some cases, the fiducial generator may be configured to generate a visual marker on tissue comprising a polygonal shape. In some cases, the fiducial generator may be configured to generate a visual marker on tissue comprising a length of at least about 1 mm. In some cases, the fiducial generator may be configured to increase a temperature of mucosa tissue to about 49° C. for less than about 2.5 seconds. In some cases, the fiducial generator may be configured to generate a visual marker on tissue configured to visually fade after about one day. In some cases, the fiducial generator may be configured to generate a visual marker on tissue comprising a depth of about 0.25 mm. In some cases, one or more of the openings of the expandable member may be configured to receive suction at a pressure between about 10 mmHg and about 200 mmHg. In some cases, one or more of the openings of the expandable member may be configured to suction tissue through the one or more of the openings. In some cases, a set of twisted pair lead wires may be coupled to the electrode array.

Bipolar high voltage treatment systems, devices, and methods in some examples can include a catheter with a tubular element having a longitudinal axis, a distal end, a lumen, an inner surface surrounding the lumen, and an outer surface. There may be an electrical insulator between the inner surface and the outer surface. The catheter may have one or more inner electrodes coupled to the inner surface, and one or more outer electrodes coupled to the outer surface. The inner electrodes and the outer electrodes may each be offset from the distal end of the catheter. The electrical insulator may separate the inner electrodes from the outer electrodes. The distal end of the catheter may be placed near a tissue to ablated. The controller may set the voltages of the inner and outer electrodes to generate an electric field outside the tubular element that induces ablation of the tissue by electroporation.

In one or more examples, the shortest path of electrical current flowing from an inner electrode to an outer electrode may be longer than the distance between the inner and outer electrode.

In one or more examples, the electrical insulator may be a dielectric, such as aluminum nitride ceramic for example. In one or more examples the conductivity of the electrical insulator may be less than 0.1 micro-Siemens per centimeter.

In one or more examples, the distance between the distal end of the catheter tubular element and each of the inner electrodes may be greater than or equal to 0.01 millimeters and less than or equal to 1 meter. In one or more examples the distance between the distal end of the catheter tubular element and each of the outer electrodes may be greater than or equal to 0.01 millimeters and less than or equal to 1 meter.

In one or more examples, the controller may set a potential difference between at least one inner electrode and at least one outer electrode of greater than 5000 volts.

In one or more examples, the controller may modify the voltages of the inner and outer electrodes within a pulse time that is less than two times the membrane recovery time of the tissue to be ablated.

In one or more examples, the controller may modify the voltages at the inner and outer electrodes within a period that is less than or equal to 10 milliseconds.

In one or more examples, the controller may modify voltages at to the inner and outer electrodes to change the direction of the electric field outside the tubular element over time. For example, the controller may set electrode voltages at one time to generate a first average electric field vector in a region of the tissue to be ablated and may set electrode voltages at another time to generate a second average electric field vector in a region of the tissue to be ablated, where the angular difference between the first and second average electric field vector is at least 1 degree.

The various examples and examples described in the summary and this document are provided not to limit or define the disclosure or the scope of the claims.

### BRIEF DESCRIPTION OF THE FIGURES

FIG. 1A shows an example ablation system including a pulsed-field ablation device having an electrode array portion.

FIG. 1B is an example illustration of a high voltage bipolar pulsing power supply driving a load.

FIG. 1C is a diagram depicting the components of a pulsed-field treatment device according to certain embodiments.

FIG. 2A shows an output waveform at the load from the bipolar pulsing power supply.

FIG. 2B shows the open and close switch logic of the switches in the bipolar pulsing power supply shown in FIG. 1 to produce the waveforms shown in FIG. 2A.

FIG. 3A shows an output waveform at the load from the bipolar pulsing power supply.

FIG. 3B shows the open and close switch logic of the switches in the bipolar pulsing power supply shown in FIG. 1 to produce the waveforms shown in FIG. 3A.

FIG. 4A shows an output waveform at the load from the bipolar pulsing power supply.

FIG. 4B shows the open and close switch logic of the switches in the bipolar pulsing power supply shown in FIG. 1 to produce the waveforms shown in FIG. 4A.

FIG. 5 shows output burst waveforms from a bipolar pulsing power supply.

FIG. 6 is an example illustration of a high voltage, bipolar, multilevel, bipolar pulsing power supply driving a load.

FIG. 7A shows an output waveform at the load from the bipolar, multilevel, pulsing power supply.

FIG. 7B shows the open and close switch logic of the switches in the bipolar, multilevel, pulsing power supply shown in FIG. 6 to produce the waveforms shown in FIG. 7A.

FIG. 8A shows an output waveform at the load from the bipolar, multilevel, pulsing power supply.

FIG. 8B shows the open and close switch logic of the switches in the bipolar, multilevel, pulsing power supply shown in FIG. 6 to produce the waveforms shown in FIG. 8A.

FIG. 9A shows an output waveform at the load from the bipolar, multilevel, pulsing power supply.

FIG. 9B shows the open and close switch logic of the switches in the bipolar, multilevel, pulsing power supply shown in FIG. 6 to produce the waveforms shown in FIG. 8A.

FIG. 10 is an example illustration of a high voltage, bipolar, multilevel, bipolar pulsing power supply driving a load.

FIG. 11 is an example illustration of a high voltage bipolar pulsing power supply driving a load.

FIG. 12A shows an output waveform at the load from the bipolar, pulsing power supply shown in FIG. 11.

FIG. 12B shows the open and close switch logic of the switches in the bipolar, pulsing power supply shown in FIG. 11 to produce the waveforms shown in FIG. 12A.

FIG. 13 is a block diagram of a computational system that can be used to with or to perform some examples described in this document.

FIG. 14A shows an alternative ablation catheter that can be used as part of system of FIG. 1A or 1C. FIG. 14B shows a cross-section view of catheter of FIG. 14A.

FIG. 15A show an alternative ablation catheter that can be used as part of system of FIG. 1A or 1C, which includes an ablation catheter with an outer electrode and an inner electrode.

FIG. 15B shows a cross-section view of catheter of FIG. 15A. FIG. 15C shows illustrative electric field vectors in the region around the distal end of the catheter of FIG. 15A; the electric field bends around the insulator at the distal end between the inner and outer electrode.

FIGS. 16A-16D show an alternative treatment catheter that can be used as part of a system of FIG. 1A or 1C.

### DETAILED DESCRIPTION

The present application provides methods and systems for treating undesirable physiological or anatomical tissue regions, such as, for example, those contributing to aberrant electrical pathways in the heart or tissues in the large intestines.

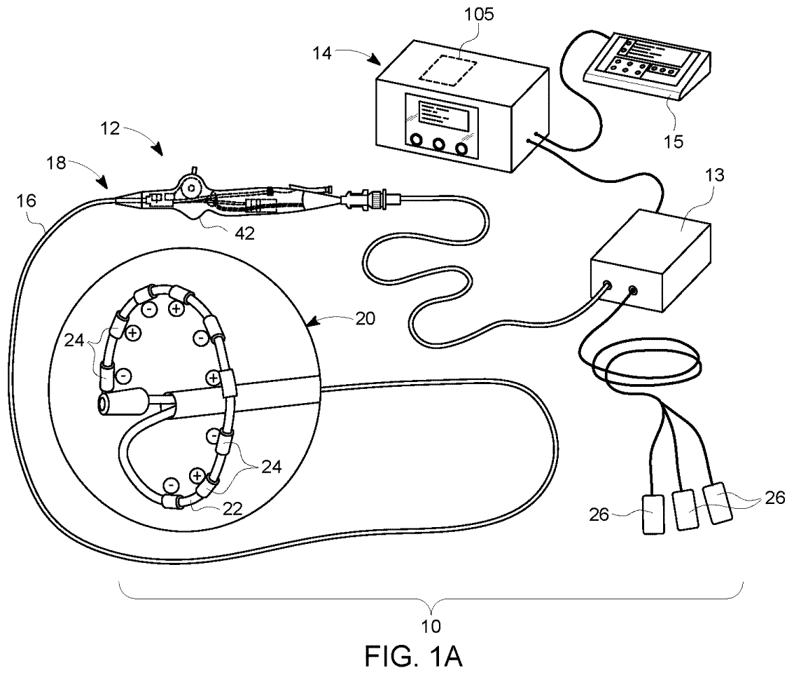

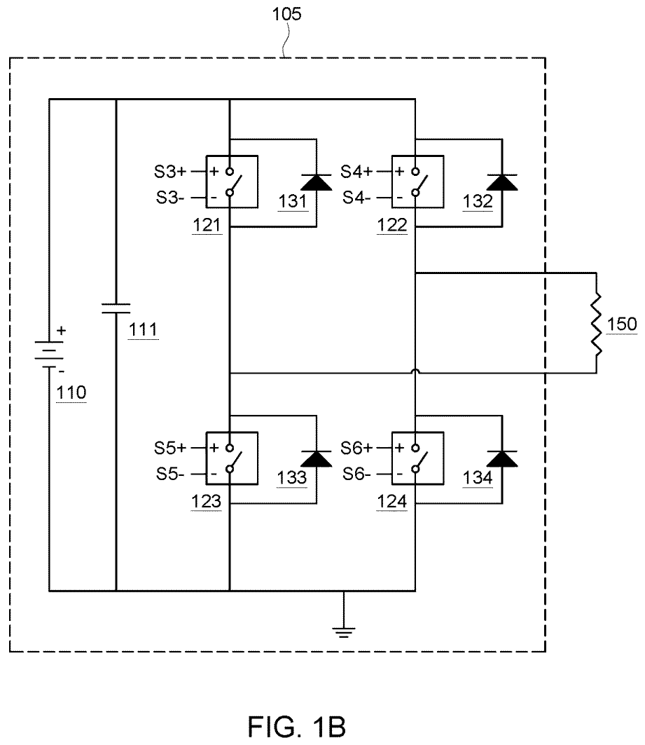

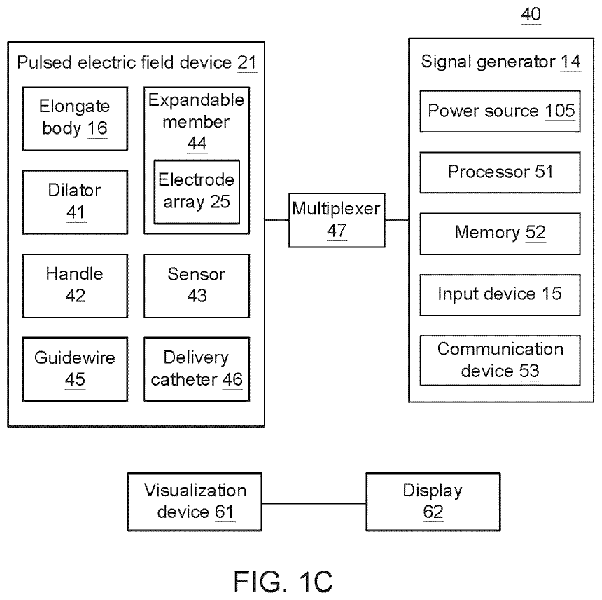

Referring now to the drawing figures in which like reference designations refer to like elements, an example of a medical system 10 is shown in FIG. 1A. The system 10 generally includes a medical device 12 that may be coupled directly to an energy supply, for example, a pulse field ablation generator 14 including a high voltage bipolar pulsing power supply 105 and an energy control, delivering and monitoring system or indirectly through a catheter electrode distribution system 13. A remote controller 15 may further be included in communication with the generator for operating and controlling the various functions of the ablation generator 14. The medical device 12 may generally include one or more treatment regions for energetic, therapeutic and/or investigatory interaction between the medical device 12 and a treatment site. The treatment region(s) may deliver, for example, pulsed electroporation energy to a tissue area in proximity to the treatment region(s).

The medical device 12 may include an elongate body 16 passable through a patient's vasculature and/or positionable proximate to a tissue region for treatment, such as a catheter, sheath, or intravascular introducer. The elongate body 16 may define a proximal portion 18 and a distal portion 20 and may further include one or more lumens disposed within the elongate body 16 thereby providing mechanical, electrical, and/or fluid communication between the proximal portion of the elongate body 16 and the distal portion of the elongate body 16. The distal portion 20 may generally define the one or more treatment region(s) of the medical device 12 that are operable to monitor, diagnose, and/or treat a portion of a patient. The treatment region(s) may have a variety of configurations to facilitate such operation. The distal portion 20 includes electrodes that form the bipolar configuration for energy delivery. In an alternate configuration, a plurality of the electrodes 24 may serve as one pole while a second device containing one or more electrodes (not pictured) would be placed to serve as the opposing pole of the bipolar configuration. For example, as shown in FIG. 1A, the distal portion 20 may include an electrode carrier arm 22 that is transitionable between a linear configuration and an expanded configuration in which the carrier arm 22 has an arcuate or substantially circular configuration. The carrier arm 22 may include the plurality of electrodes 24 (for example, nine electrodes 24, as shown in FIG. 1A) that are configured to deliver pulsed-field energy. Alternatively, the medical device 12 may have a linear configuration with the plurality of electrodes 24. For example, the distal portion 20 may include six electrodes 24 linearly disposed along a common longitudinal axis.

The ablation generator 14 may include processing circuitry, such as a processor 17 communication with one or more controllers and/or memories containing software modules containing instructions or algorithms to provide for the automated operation and performance of the features, sequences, calculations, or procedures described herein. The system 10 may further include three or more surface ECG electrodes 26 on the patient in communication with the ablation generator 14 through the catheter electrode distribution box 13 to monitor the patient's cardiac activity for use in determining pulse train delivery timing at the desired portion of the cardiac cycle, for example, during the ventricular refractory period. In addition to monitoring, recording or otherwise conveying measurements or conditions within the medical device 12 or the ambient environment at the distal portion of the medical device 12, additional measurements may be made through connections to the multi-electrode catheter including for example temperature, electrode-tissue interface impedance, delivered charge, current, power, voltage, work, or the like in the ablation generator 14 and/or the medical device 12. The surface ECG electrodes 26 may be in communication with the ablation generator 14 for initiating or triggering one or more alerts or therapeutic deliveries during operation of the medical device 12. Additional neutral electrode patient ground patches (not pictured) may be employed to evaluate the desired bipolar electrical path impedance, as well as monitor and alert the operator upon detection of inappropriate and/or unsafe conditions, which include, for example, improper (either excessive or inadequate) delivery of charge, current, power, voltage and work performed by the plurality of electrodes 24; improper and/or excessive temperatures of the plurality of electrodes 24, improper electrode-tissue interface impedances; improper and/or inadvertent electrical connection to the patient prior to delivery of high voltage energy by delivering one or more low voltage test pulses to evaluate the integrity of the tissue electrical path.

The ablation generator 14 may include an electrical current or pulse generator having a plurality of output channels, with each channel coupled to an individual electrode of the plurality of electrodes 24 or multiple electrodes of the plurality of electrodes 24 of the medical device 12. The ablation generator 14 may be operable in one or more modes of operation, including for example: (i) bipolar energy delivery between at least two electrodes 24 or electrically-conductive portions of the medical device 12 within a patient's body, (ii) monopolar or unipolar energy delivery to one or more of the electrodes or electrically-conductive portions on the medical device 12 within a patient's body and through either a second device within the body (not shown) or a patient return or ground electrode (not shown) spaced apart from the plurality of electrodes 24 of the medical device 12, such as on a patient's skin or on an auxiliary device positioned within the patient away from the medical device 12, for example, and (iii) a combination of the monopolar and bipolar modes.

The ablation generator 14 may provide electrical pulses to the medical device 12 to perform an electroporation procedure to cardiac tissue or other tissues within the body, for example, renal tissue, airway tissue, and organs or tissue within the cardiothoracic space. “Electroporation” utilizes high amplitude pulses to effectuate a physiological modification (i.e., permeabilization) of the cells to which the energy is applied. Such pulses may preferably be short (e.g., nanosecond, microsecond, or millisecond pulse width) in order to allow application of high voltage, high current (for example, 20 or more amps) without long duration of electrical current flow that results in significant tissue heating and muscle stimulation. In particular, the pulsed energy induces the formation of microscopic pores or openings in the cell membrane. Depending upon the characteristics of the electrical pulses, an electroporated cell can survive electroporation (i.e., “reversible electroporation”) or die (i.e., irreversible electroporation, “IEP”). Reversible electroporation may be used to transfer agents, including large molecules, into targeted cells for various purposes, including alteration of the action potentials of cardiac myocyctes.

The ablation generator 14 may be configured and programmed to deliver pulsed, high voltage electric fields appropriate for achieving desired pulsed, high voltage ablation (or pulsed field ablation). As a point of reference, the pulsed, high voltage, non-radiofrequency, ablation effects of the present disclosure are distinguishable from DC current ablation, as well as thermally induced ablation attendant with conventional RF techniques. For example, the pulse trains delivered by ablation generator 14 are delivered at a pulse repetition frequency less than 3 kHz, and in an example configuration, 1 kHz, which is a lower frequency than radiofrequency treatments. The pulsed-field energy in accordance with the present disclosure is sufficient to induce cell death for purposes of completely blocking an aberrant conductive pathway along or through cardiac tissue, destroying the ability of the so-ablated cardiac tissue to propagate or conduct cardiac depolarization waveforms and associated electrical signals.

The plurality of electrodes 24 may also perform diagnostic functions such as collection of intracardiac electrograms (EGM) as well as performing selective pacing of intracardiac sites for diagnostic purposes. In one configuration, the measured ECG signals, are transferred from the catheter electrode energy distribution system 13 to an EP recording system input box (not shown) which is included with ablation generator 14. The plurality of electrodes 24 may also monitor the proximity to target tissues and quality of contact with such tissues using impedance-based measurements with connections to the catheter electrode energy distribution system 13. The catheter electrode energy distribution system 13 may include high speed relays to disconnect/reconnected specific electrode 24 from the ablation generator 14 during therapies. Immediately following the pulsed energy deliveries, the relays reconnect the electrodes 24 so they may be used for diagnostic purposes.

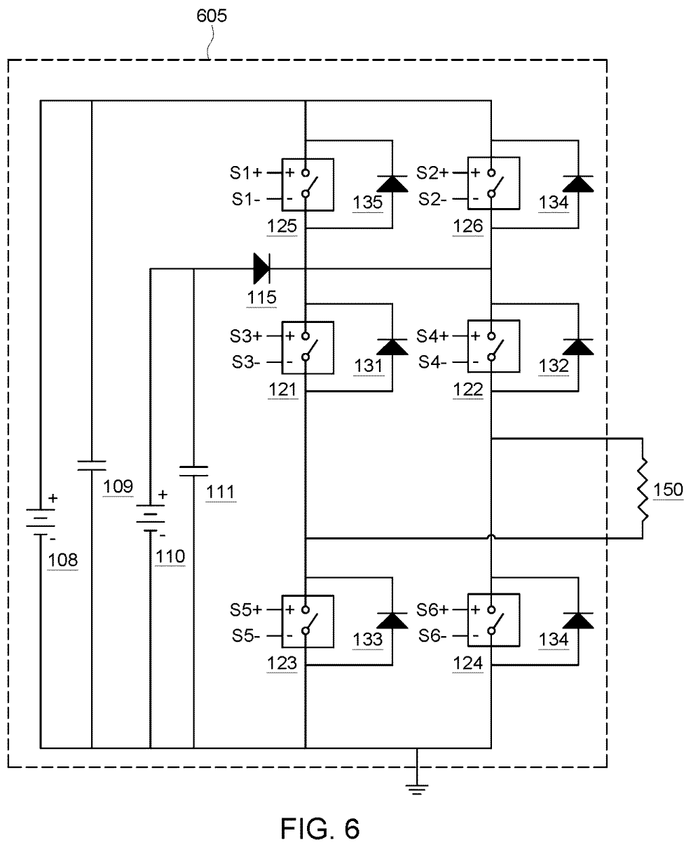

As shown in FIGS. 1A and 1B, ablation generator 14 can include a bipolar high voltage bipolar pulsing power supply 105. Alternatively, ablation generator 14 can include a power supply 605 or 1005 as depicted in FIGS. 6, 10, and 11. A high voltage bipolar pulsing power supply used in system 10 can produce high voltage bipolar pulses that include a positive high voltage pulse greater than about 100 V, 200 V, 500 V, 1 kV, 2 kV, 5 kV, 10 kV, etc. followed by a negative high voltage pulse less than about −100 V, −200 V, −500 V, −1 kV, −2 kV, −5 kV, 10 kV etc. with a positive to negative dwell between the positive high voltage pulse and the negative high voltage pulse. The high voltage bipolar pulsing power supply can reproduce these high voltage pulses with a high pulse repetition frequency greater than about 10 kHz.

FIG. 1B is an example illustration of a high voltage bipolar pulsing power supply 105 driving a load 150.

The high voltage bipolar pulsing power supply 105 may include a first DC source 110 and an energy storage capacitor 111. The first DC source 110, for example, may include a high voltage bipolar pulsing power supply that charges the energy storage capacitor 111. The energy storage capacitor 111, for example, may include a capacitor having a capacitance of about 80 nF to about 250 nF or about 2 μF to 100 μF.

The high voltage bipolar pulsing power supply 105, for example, may include the first switch circuit 121, the second switch circuit 122, the third switch circuit 123, and the fourth switch circuit 124. Each of the switch circuits 121, 122, 123, or 124, for example, may include a plurality of switches in series or in parallel such as, for example, four switches, eight switches, twelve switches, etc. arranged in parallel.

The first switch circuit 121 may be coupled with the first DC source 110 and a first side of load 150. The third switch circuit 123 may be coupled with ground and the first side of load 150 and first switch circuit 121. The second switch circuit 122 may be coupled with the first DC source 110 and a second side of the load 150. The fourth switch circuit 124 may be coupled with ground, the second side of load 150, and the second switch circuit 122.

Each of the switch circuits 121, 122, 123, and 124, for example, may include one or more of any type of solid-state switch such as, for example, IGBTs, a MOSFETs, a SiC MOSFETs, SiC junction transistors, FETs, SiC switches, GaN switches, photoconductive switches, etc. Each of the switch circuits 121, 122, 123, and 124 may be switched at high frequencies and/or may produce high voltage pulses. These frequencies may, for example, include frequencies of about 1 kHz, 5 kHz, 10 kHz, 25 kHz, 50 kHz, 100 kHz, etc.

Each switch of the switch circuits 121, 122, 123, and 124 may be coupled in parallel with a respective bridge diode, may have a stray capacitance, and/or may have stray inductance. The stray inductances of each of the switch circuits 121, 122, 123, and 124 may be substantially equal. The stray inductances of each of the switch circuits 121, 122, 123, and 124, for example, may be less than about 5 nH, 10 nH, 50 nH, 100 nH, 150 nH, etc. The stray capacitance of each of the switch circuits 121, 122, 123, and 124, for example, may be low such as, for example, less than about 400 nF, 200 nF, 100 nF, 50 nF, 25 nF, 10 nF, etc. If each switch of the switch circuits 121, 122, 123, and 124 may include multiple individual switches, then the combination of the multiple individual switches may have a capacitance of less than about 150 nF, 100 nF, 50 nF, 25 nF 10 nF, 5 nF, etc.

The combination of a switch (e.g., one of the switch circuits 121, 122, 123, or 124), a respective diode (e.g., one of diodes 131, 132, 133, and 134), and related circuitry may have a stray inductance of less than about 5 nH, 10 nH, 50 nH, 100 nH, 150 nH, etc. The high voltage bipolar pulsing power supply 105 may include low stray inductance throughout the circuit such as, for example, an inductance less than about 5 nH, 10 nH, 50 nH, 100 nH, 150 nH, 200 nH, etc.

The load 150 may include any type of load. For example, the load 150 may have an output resistance less than about 250 ohms, 100 ohms, 50 ohms, 25 ohms, 10 ohms, 5 ohms, 2 ohms, 1 ohm, etc. The load 150 may be part of an electrode for ablation and/or an electrode for electroporation, such as electrodes 24 shown in FIG. 1A. The load 150 may include a transformer that may be used to increase the power produced by the high voltage bipolar pulsing power supply 105.

FIG. 1C depicts the components of a pulsed-field treatment device according to certain embodiments.

Systems described here may include one or more of the components used to treat tissue, such as, for example, a pulsed electric field device and a visualization device. FIG. 1C is a block diagram of a variation of a pulsed electric field system 40 comprising one or more of a pulsed electric field device 41, a signal generator 14, multiplexer 47, a visualization device 61, and a display 62.

In some cases, the pulsed electric field device 21 may include one or more (e.g., a first and a second) elongate bodies 16 sized and shaped to be placed in one or more body cavities of the patient such as, for example, an esophagus, a stomach, and small intestine. In some cases, the pulsed electric field device 21 may further include one or more expandable members 44, one or more electrode arrays 25, one or more dilators 41, a handle 42, one or more sensors 43, a guidewire 45, and a delivery catheter 46. A distal end of the pulsed electric field device 21 may include the dilator 41, and the guidewire 45 may extend from a lumen of the dilator 41. The expandable member 44 may include the electrode array 25. For example, as will be described in more detail herein. In some cases the electrode array 25 may be coupled to a surface (e.g., outer surface) of the expandable member 25, while in other variations, the electrode array itself may form the expandable member and/or the electrode array may be integral with the expandable member. In some cases, the expandable member 44 and/or the electrode array 25 may be disposed adjacent to one or more dilators, for example, between at least a pair of dilators 41. In some cases, the pulsed electric field system 40 may optionally include a delivery catheter 46 configured to advance over the pulsed electric field device 41. Additionally or alternatively, the pulsed electric field device 21 may include one or more sensors 43 configured to measure one or more predetermined characteristics such as temperature, pressure, impedance and the like.

As mentioned above, the pulsed electric field system 40 may include a visualization device 61. In some cases, the visualization device 61 may be configured to visualize one or more steps of a treatment procedure. The visualization device 61 may aid one or more of advancement of the pulsed electric field device 41, positioning of the pulsed electric field device and/or components thereof (e.g., the electrode array 25), and confirmation of the treatment procedure. For example, the visualization device 61 may be configured to generate an image signal that is transmitted to a display 62 or output device. In some cases, the visualization device 61 may be advanced separately from and alongside the pulsed electric field device 21 during the treatment procedure. For example, an expandable member 44 of the pulsed electric field device 21 may be configured to hold the visualization device 61 such that the pulsed electric field device 21 translates together with the visualization device 61 as they are moved through the body. The expandable member 44 may expand to release the visualization device 61, thus allowing freedom of movement for the visualization device 61. In other variations, the visualization device 61 may be integrated with the pulsed electric field device 61. For example, the dilator 41 may include the visualization device 61.

The visualization device 61 may be any device (internal or external to the body) that assists a user in visualizing a treatment procedure. In some cases, the visualization device 61 may include one or more of an endoscope (e.g., chip-on-the-tip camera endoscope, three camera endoscope), image sensor (e.g., CMOS or CCD array with or without a color filter array and associated processing circuitry), camera, fiberscope, external light source, and ultrasonic catheter. In some cases, an external light source (e.g., laser, LED, lamp, or the like) may generate light that may be carried by fiber optic cables. Additionally or alternatively, the visualization device 61 may include one or more LEDs to provide illumination. For example, the visualization device 61 may include a bundle of flexible optical fibers (e.g., a fiberscope). The bundle of fiber optic cables or fiberscope may be configured to receive and propagate light from an external light source. The fiberscope may include an image sensor configured to receive reflected light from the tissue and the pulsed electric field device. It should be appreciated that the visualization device 61 may include any device or devices that allows for or facilitates visualization of any portion of the pulsed electric field device and/or of the internal structures of the body. For example, the visualization device may include a capacitive sensor array and/or a fluoroscopic technique for real-time X-ray imaging.

In some cases, the signal generator 14 may be configured to provide energy (e.g., energy waveforms, pulse waveform) to the pulsed electric field device 21 to treat predetermined portions of tissue, such as, for example, duodenal tissue. In some cases, a PEF system as described herein may include a signal generator that includes an energy source and a processor. The signal generator may be configured to deliver a bipolar waveform to an electrode array, which may deliver energy to the tissue (e.g., duodenal tissue). The delivered energy may aid in resurfacing the mucosa of the duodenum while minimizing damage to surrounding tissue. In some cases, the signal generator may generate one or more bipolar waveforms. In some cases, the signal generator may be configured to control waveform generation and delivery in response to received sensor data. For example, energy delivery may be modulated (e.g., inhibited) unless a measured temperature falls within a predetermined range.

In some cases, in order to limit nerve stimulation, a pulse waveform may, on average, include a net current of about zero (e.g., generally balanced positive and negative current), and have a non-zero time of less than about 2 μsec or less than about 5 μsec. In some cases, the pulse waveform may include a square waveform. For example, the pulse waveform may include a square shape in voltage drive and in current drive, or the pulse waveform may include a square shape in voltage drive and a sawtooth shape in current drive. In some cases, one or more pulses may include a half sinewave for both current and voltage. In some cases, one or more pulses may include two exponentials with different rise and fall times. In some cases, one or more pulses may include bipolar pulse at a first potential followed by pulse pairs at a second potential less than the first potential.

In some cases, a multiplexer 47 may be coupled to the pulsed electric field device 41. For example, the multiplexer 47 may be coupled between the signal generator 14 and the pulsed electric field device 41, or the signal generator 14 may include the multiplexer 47. The multiplexer 47 may be configured to select a subset of electrodes of an electrode array 25 receiving a pulse waveform generated by the signal generator 14 according to a predetermined sequence. Additionally or alternatively, the multiplexer 47 may be coupled to a plurality of signal generators and may be configured to select between a waveform generated by one of the plurality of signal generators 14 for a selected subset of electrodes.

Generally, the pulsed electric field devices described herein may include an elongate body and an expandable member comprising an electrode array. The pulsed electric field devices may be configured to facilitate deployment in, and treatment of, the duodenum. In some cases, the pulsed electric field device may be configured to apply pulsed or modulated electric field energy to an inner circumference of the duodenum. The devices described herein may be used to treat only a particular, pre-specified portion of the duodenum, and/or an entire length of the duodenum. In some cases, an electrode array of the pulsed electric field device may generate an electric field strength of from about 400 V/cm to about 1500 V/cm, from about 1500 V/cm to about 4500 V/cm, including all values and sub-ranges in-between, at a treatment depth of from about 0.5 mm to about 1.5 mm from an inner surface of the duodenum, for example, at about 1 mm. In some cases, the electric field may decay such that the electric field strength is less than about 400 V/cm at about 3 mm from the inner surface of the duodenum. In some cases, a predetermined bipolar current and voltage sequence may be applied to an electrode array of the pulsed electric field device to generate the pulsed or modulated electric field. The generated pulsed or modulated electric field may be substantially uniform to robustly induce cell lysis in a predetermined portion of duodenal tissue. For example, a generated pulsed or modulated electric field may spatially vary up to about 20% at a predetermined depth of tissue, between about 5% and about 20%, between about 10% and 20%, and between about 5% and about 15%, including all ranges and sub-values in-between. Furthermore, the pulsed electric

Generally, the expandable members described here may be configured to change configurations to aid in positioning of the electrode array relative to the duodenum during a treatment procedure. For example, the expandable member may expand to contact tissue to hold the pulsed electric field device in place (e.g., elongate body, electrode array, sensor) relative to the tissue. The expandable member may also partially expand to hold a visualization device in place relative to the pulsed electric field device. The expandable members may include a compressed configuration and an expanded configuration. As will be discussed in more detail herein, in some instances, the compressed configuration may be a rolled configuration and the expanded configuration may be an unrolled configuration. Moreover. In some cases, the expandable member may include a semi-expanded (or partially unrolled) configuration between the compressed configuration and the expanded configuration. Placing the expandable member in the compressed configuration may allow the pulsed electric field device to be compact in size, which may allow for easier advancement through one or more body cavities. Once appropriately positioned, the expandable member may be transitioned to the expanded configuration, which may allow an electrode array of the expandable member to contact all or a portion of an inner circumference of the duodenum. In some cases, the semi-expanded configuration may allow the expandable member to hold another device (e.g., visualization device) within a lumen of the expandable member. Additionally or alternatively, a lumen may refer to a tubular or non-tubular structure having one or more openings, apertures, holes, slots, combinations thereof, and the like.

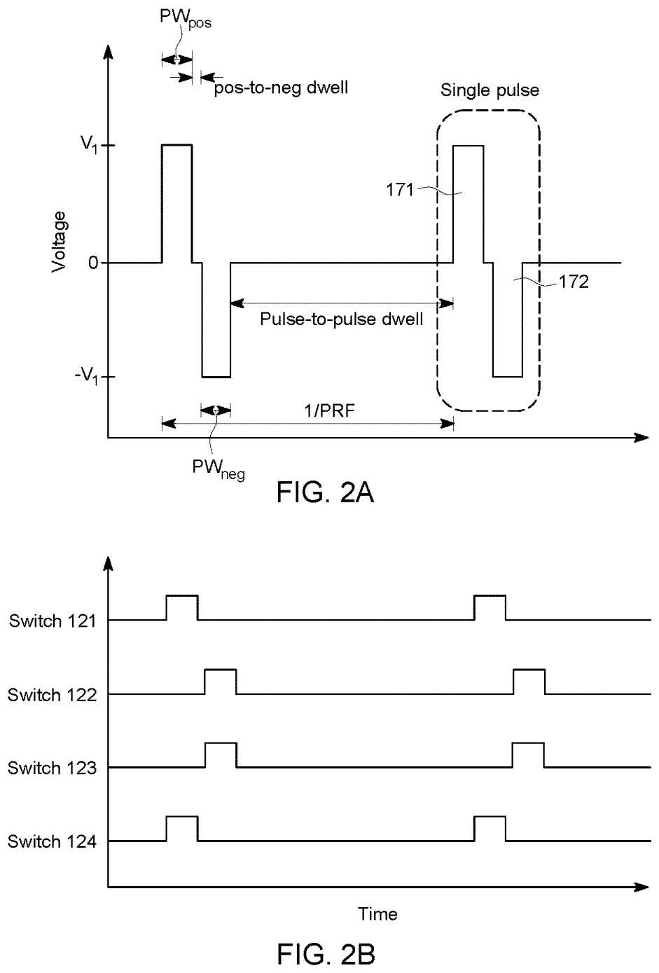

FIG. 2A shows an output waveform at the load 150 from the high voltage bipolar pulsing power supply 105. FIG. 2B shows the open and close switch logic of the switch circuits 121, 122, 123, and 124 to produce the waveforms shown in FIG. 2A. This output waveform includes a positive pulse 171 and a negative pulse 172. When the first switch circuit 121 and the fourth switch circuit 124 are closed and the second switch circuit 122 and the third switch circuit 123 are open the positive pulse 171 is formed. When the second switch circuit 122 and the third switch circuit 123 are closed and the first switch circuit 121 and the fourth switch circuit 124 are open the negative pulse 172 is formed.

Each positive pulse 171 in FIG. 2A has a voltage of V₁ and each negative pulse 172 in FIG. 2A has a negative voltage of −V₁. The voltage Vᵢ is the voltage from the energy storage capacitor 111 and/or the first DC source 110, V₁. The time between the positive pulse 171 and the 172 is the dwell. The time between each consecutive positive pulse 171 is the inverse of the pulse repetition frequency (1/PRF). The time between the end of the first negative pulse 172 and the start of the first positive pulse is the pulse-to-pulse dwell. The pulse width of the positive pulse is the PWₚₒₛ and the pulse width of the negative pulse is the PW_{neg}.

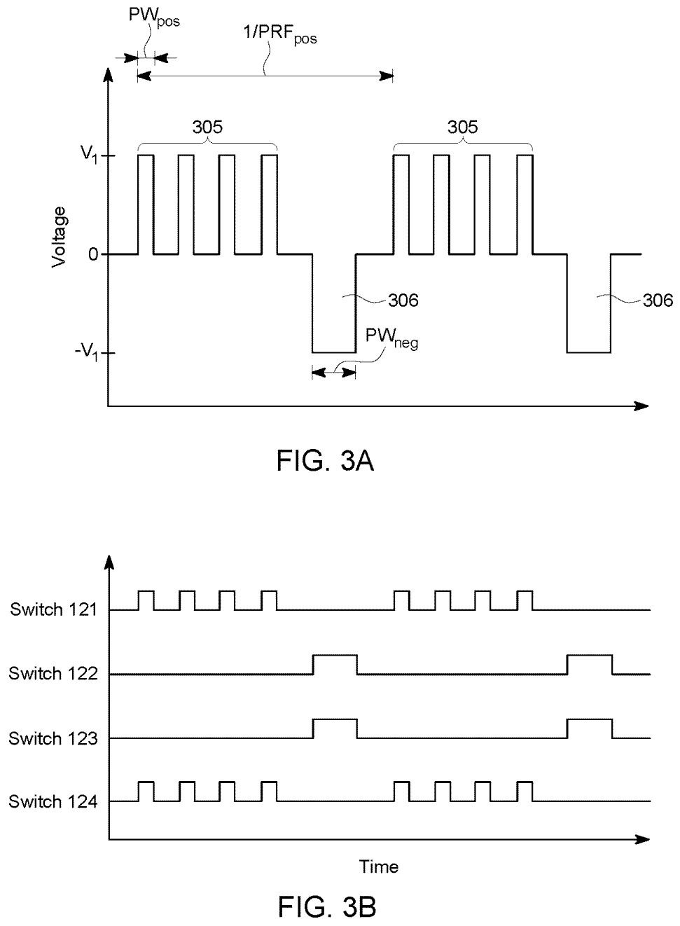

FIG. 3A shows an output waveform at the load 150 from the high voltage bipolar pulsing power supply 105 with a plurality of positive pulses 305 followed by a negative pulse 306. FIG. 3B shows the open and close switch logic of the switch circuits 121, 122, 123, and 124 to produce the waveforms shown in FIG. 3A. This output waveform includes a plurality of positive pulses 305 and a longer negative pulse 306. When the first switch circuit 121 and the fourth switch circuit 124 are closed and the second switch circuit 122 and the third switch circuit 123 are open the each one of the plurality of positive pulses 305 are formed. When the second switch circuit 122 and the third switch circuit 123 are closed and the first switch circuit 121 and the fourth switch circuit 124 are open the negative pulse 306 is formed.

Each positive pulse of the plurality of positive pulses 305 in FIG. 3A has a voltage of V₁ and each negative pulse 306 in FIG. 3A has a negative voltage of −V₁. The voltage Vᵢ is the voltage from the energy storage capacitor 111 and/or the first DC source 110, V₁. Each pulse of the plurality of pulses 305 may have a pulse width of PWₚₒₛ, and the pulse width of the negative pulse is the PW_{neg}. The time between the first pulse of the plurality of positive pulses 305 and the next first pulse of the plurality of pulses 305 is the pulse repetition frequency (1/PRF).

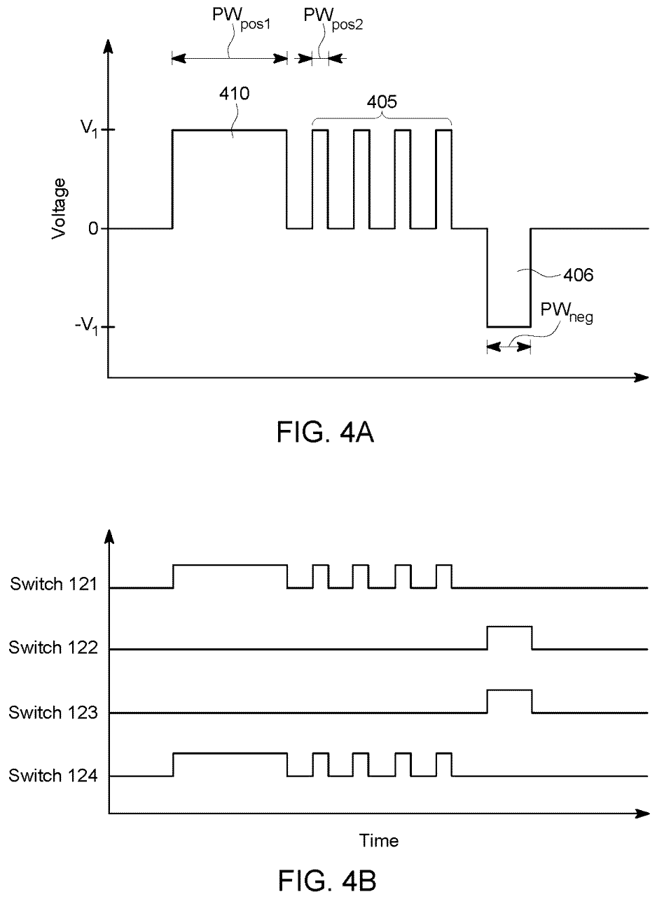

FIG. 4A shows an output waveform at the load 150 from the high voltage bipolar pulsing power supply 105 with a positive first longer pulse 410, a plurality of positive pulses 405 followed by a negative pulse 406. FIG. 3B shows the open and close switch logic of the switch circuits 121, 122, 123, and 124 to produce the waveforms shown in FIG. 4A. When the first switch circuit 121 and the fourth switch circuit 124 are closed and the second switch circuit 122 and the third switch circuit 123 are open the each one of the first positive pulse 410 and the plurality of positive pulses 405 are formed. When the second switch circuit 122 and the third switch circuit 123 are closed and the first switch circuit 121 and the fourth switch circuit 124 are open the negative pulse 406 is formed.

Each positive pulse of the plurality of positive pulses 405 and the long pulse 410 in FIG. 4A has a voltage of Vᵢ and each negative pulse 406 in FIG. 4A has a negative voltage of −V₁. The voltage V₁ is the voltage from the energy storage capacitor 111 and/or the first DC source 110, V₁. Each pulse of the plurality of pulses 405 may have a pulse width of PWₚₒₛ₂, the long positive pulse 410 may have a pulse width of PWₚₒₛ₁, and the pulse width of the negative pulse is the PW_{neg}. The pulse width PWₚₒₛ₁ of the long pulse may be longer than the pulse width PWₚₒₛ₂ of each of the plurality of positive pulses 405 such as, for example, substantially more than two, three, four, five, ten, twenty, fifty, one hundred, five hundred, etc. times as long.

The time between the first pulse of the plurality of positive pulses 305 and the next first pulse of the plurality of pulses 305 is the pulse repetition frequency (1/PRF).

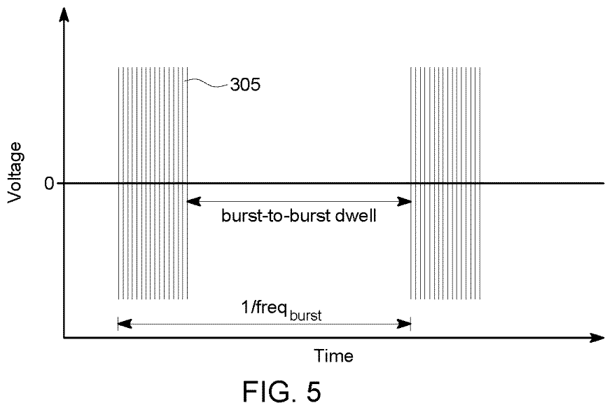

As shown in FIG. 5, the high voltage bipolar pulsing power supply 105 can produce burst pulses 305 that includes a plurality of bipolar pulses. The time between consecutive bursts is the burst-to-burst dwell and the time between the start of a first burst and the start of a second burst is the inverse of burst frequency (1/freq_{burst}).

A controller (e.g., computational system 1300) may be coupled with each switch (e.g., the first switch circuit 121, the second switch circuit 122, the third switch circuit 123, and the fourth switch circuit 124) may control the opening and closing of these switch circuits. The controller may control the switch circuits to produce the waveforms shown in FIG. 2A by opening closing the switch circuits as shown in FIG. 2B. The controller may control the timing of the switch circuits to produce the waveforms shown in FIG. 3.

The controller can control the switch circuits to produce long pulse widths with a low pulse repetition frequency (PRF). For example, the controller can close the first switch circuit 121 and the fourth switch circuit 124 for a long duration (e.g., 5 ms, 2.5 ms, 1 ms, 500 ns, etc.), then open the first switch circuit 121 and the fourth switch circuit 124 and close the second switch circuit 122 and the third switch circuit 123 for a long duration (e.g., 5 ms, 2.5 ms, 1 ms, 500 ns, etc.), and then open the second switch circuit 122 and the third switch circuit 123. The controller can repeat this process after any period of time such as, for example, a pulse repetition frequency of 1 kHz, 10 kHz, 100 kHz, etc.

The controller can control the switch circuits to produce a plurality of short pulses (e.g., 250 ns, 500 ns, 1 ms, 5 ms, etc.) with a high pulse repetition frequency (e.g., 1 kHz, 5 kHz, 10 kHz, 25 kHz, etc.) within a burst and repeat the burst after a period of time (e.g., 250 ms, 500 ms, 1 s, 3 s, 5 s, etc.) such as, for example, as shown in FIG. 3. The controller can repeat these bursts, for example, hundreds or thousands of times.

FIG. 6 shows an example high voltage, multilevel, bipolar pulsing power supply 605 driving the load 150. The high voltage, multilevel, bipolar pulsing power supply 605 includes the high voltage bipolar pulsing power supply 105 and a fifth switch circuit 125 with a corresponding diode 135, a sixth switch circuit 126 with a corresponding diode 136, a second DC source 108, and a second energy storage capacitor 109. The fifth switch circuit 125 is coupled between the second DC source 108 and the first switch circuit 121. The sixth switch circuit 126 is coupled between the second DC source 108 and the second switch circuit 122. A diode may be included between the second DC source 108 and the fifth switch circuit 125 and between the second DC source 108 and the sixth switch circuit 126.

The second DC source 108 can produce a voltage greater than the first DC source 110.

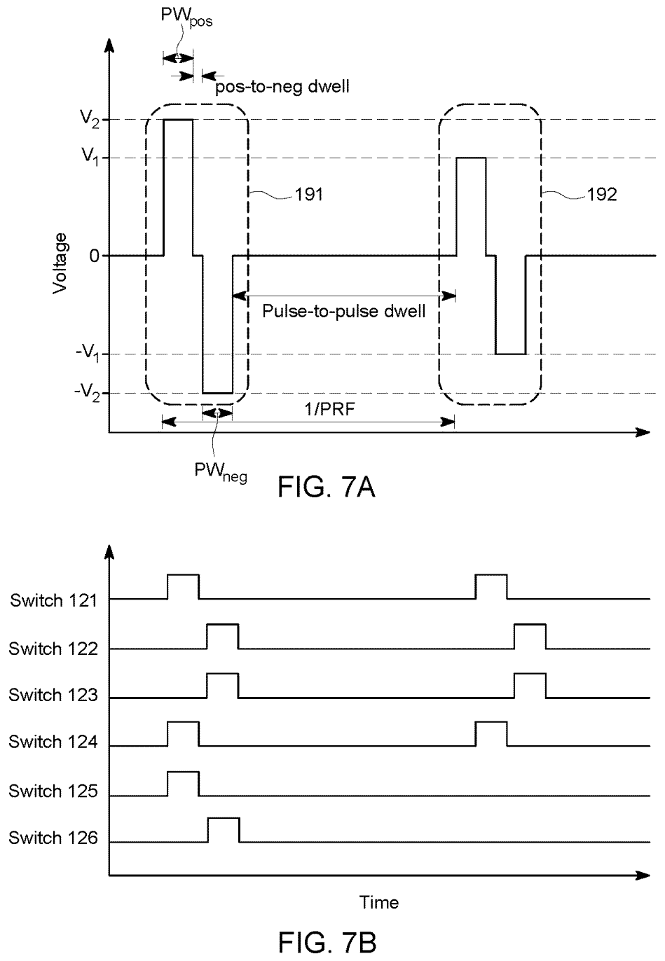

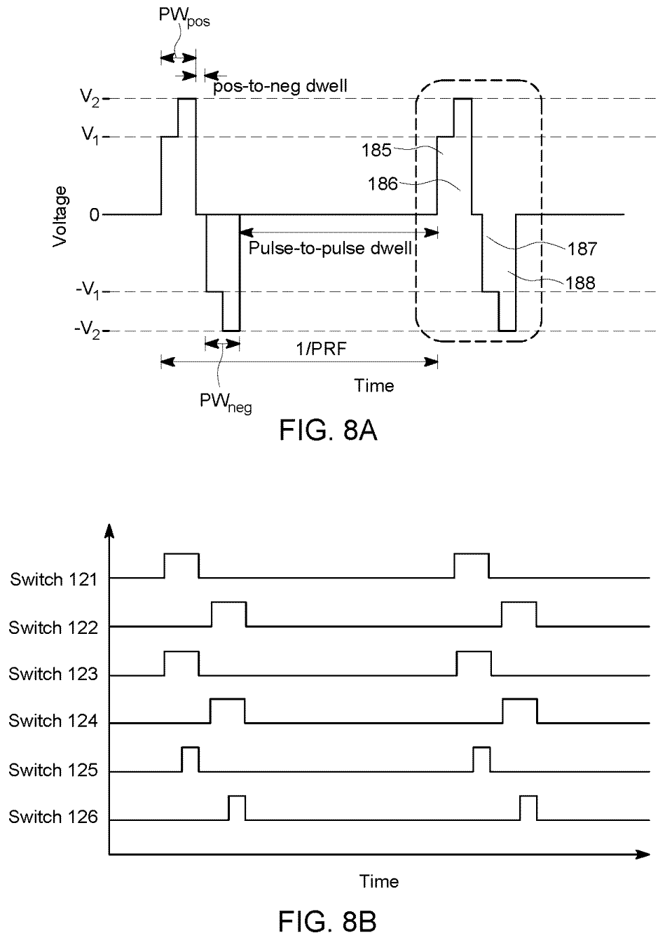

The diode 115 ensures charge flows from the energy storage capacitor 111, through the closed switch circuits, either the first switch circuit 121 and the fourth switch circuit 124 or the second switch circuit 122 and the third switch circuit 123 to the load 150. The high voltage, multilevel, bipolar pulsing power supply 605 can produce either 1) bipolar pulses with a high voltage as shown in FIG. 7A or 2) bipolar and multilevel pulses as shown in FIG. 8A. In FIG. 7A the first pulse 191 has a voltage of V₁, which is the voltage of first DC source 110, and the second pulse 192 has a voltage V₂, which is the voltage of the second DC source 108.

FIG. 7B shows the shows the open and close switch logic of the switch circuits 121, 122, 123, 124, 125, and 126, to produce the bipolar waveforms shown in FIG. 7A. The positive portion of the first pulse 191 is formed with a voltage V₂, when the fifth switch circuit 125, the first switch circuit 121, and the fourth switch circuit 124 are closed and the sixth switch circuit 126, the second switch circuit 122 and the third switch circuit 123 are open. The negative portion of the first pulse 191 is formed with a voltage V₂, when the sixth switch circuit 126, the second switch circuit 122, and the third switch circuit 123 are closed and the fifth switch circuit 125, the first switch circuit 121, and the fourth switch circuit 124 are open. The positive portion of the second pulse 192 is formed with a voltage V₁, when the first switch circuit 121 and the fourth switch circuit 124 are closed and the sixth switch circuit 126, the second switch circuit 122, the fifth switch circuit 125, and the third switch circuit 123 are open. The negative portion of the second pulse 192 is formed with a voltage V₂, when the second switch circuit 122 and the third switch circuit 123 are closed and the fifth switch circuit 125, the sixth switch circuit 126, the first switch circuit 121, and the fourth switch circuit 124 are open.

FIG. 8B shows the shows the open and close switch logic of the switch circuits 121, 122, 123, 124, 125, and 126 to produce the multilevel bipolar waveforms shown in FIG. 8A. When the first switch circuit 121 and the fourth switch circuit 124 are closed and the fifth switch circuit 125, the sixth switch circuit 126, the second switch circuit 122, and the third switch circuit 123 are open, first level positive pulse 185 is formed at voltage V₁. When the switch, 125, the first switch circuit 121 and the fourth switch circuit 124 are closed and the sixth switch circuit 126, the second switch circuit 122, and the third switch circuit 123 are open, the second level positive pulse 186 is formed at voltage V₂. The combination of the first level positive pulse 185 and the second level positive pulse 186 forms a multilevel positive pulse. When the second switch circuit 122 and the third switch circuit 123 are closed and the fifth switch circuit 125, the sixth switch circuit 126, the first switch circuit 121, and the fourth switch circuit 124 are open, the first level negative pulse 187 is formed at voltage −V₁. When the switch, 126, the second switch circuit 122, and the third switch circuit 123 are closed and the fifth switch circuit 125, the first switch circuit 121, and the fourth switch circuit 124 are open, second level negative pulse 188 is formed at voltage −V₂. The combination of the first level negative pulse 187 and the second level negative pulse 188 forms a multilevel negative pulse. The V₂ is the voltage of the second DC source 108.

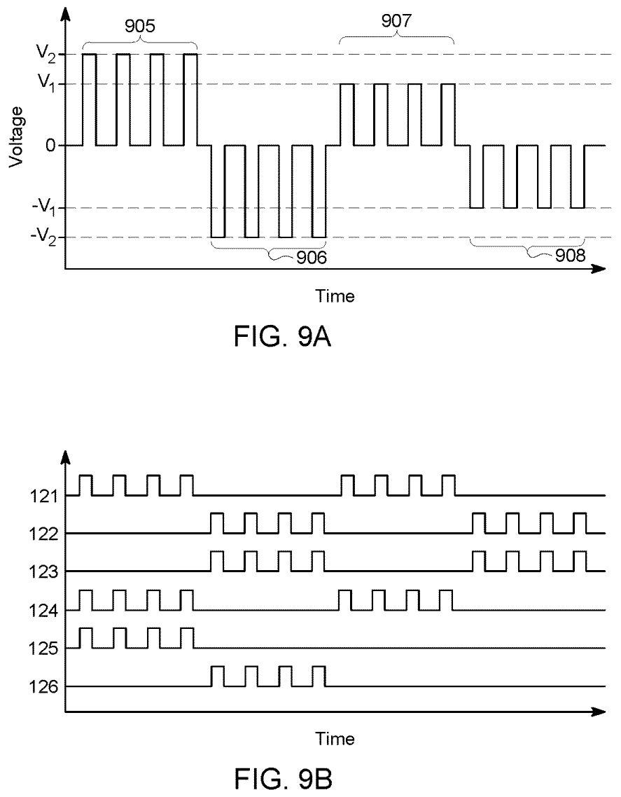

FIG. 9B shows the shows the open and close switch logic of the switch circuits 121, 122, 123, 124, 125, and 126 to produce the multilevel bipolar waveforms shown in FIG. 9A. FIG. 9A shows a first burst of pulses 905 having a voltage V₂, a second burst of pulses 906 having a negative voltage V₂, a third burst of pulses 907 having a voltage V₁, and a fourth burst of pulses 908 having a negative voltage V₁. The first burst of pulses 905 may include any number of pulses; the second burst of pulses 906 may include any number of pulses; the third burst of pulses 907 may include any number of pulses; and/or the fourth burst of pulses 908 may include any number of pulses. The bursts of pulses may occur in any order or sequence. The first burst of pulses 905, the second plurality of pulses 906, the third plurality of pulses 907, and/or the fourth plurality of pulses 908 may have any pulse repetition frequency and/or each pulse of the plurality of pulses may have any pulse widths.

The first burst of pulses 905 with a voltage V₂ may be created by closing the first switch circuit 121, the fourth switch circuit 124, and the fifth switch circuit 125; and opening the second switch circuit 122, the third switch circuit 123, and the sixth switch circuit 126. The second burst of pulses 906 with a negative voltage V₂ may be created by closing the second switch circuit 122, the third switch circuit 123, and the sixth switch circuit 126; and opening the first switch circuit 121, the fourth switch circuit 124, and the fifth switch circuit 125. The third burst of pulses 907 with a voltage V₁ may be created by closing the first switch circuit 121 and the fourth switch circuit 124; and opening the second switch circuit 122, the third switch circuit 123, the fifth switch 125, and the sixth switch 126. The fourth burst of pulses 908 with a negative voltage V₁ may be created by closing the second switch circuit 122 and the third switch circuit 123; and opening the first switch circuit 121, the fourth switch circuit 124, the fifth switch 125, and the sixth switch 126.

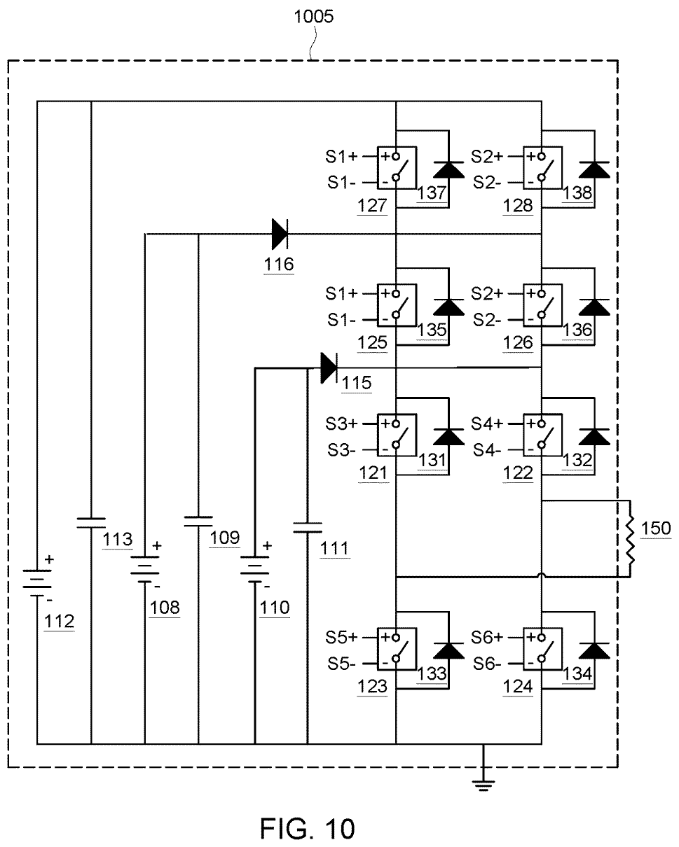

The bipolar pulsing power supply 605 may include additional switch circuit to produce additional multilevel pulses. FIG. 10 shows an example high voltage, multilevel, bipolar pulsing power supply 1005 with a seventh switch circuit 127 and an eighth switch circuit 128 coupled with a third DC source 112 and a third energy storage capacitor 113. The seventh switch circuit 127 may include a corresponding diode 137 and the eighth switch circuit 128 may include a corresponding diode 138. An additional diode 116 may also be included between the second DC source 108 and the second energy storage capacitor 109 and both the fifth switch circuit 125 and the sixth switch circuit 126. The third DC source 112 may have a voltage greater than the first DC source 110 and/or the second DC source 108. The high voltage bipolar pulsing power supply 1005 may produce multilevel pulses with three levels of voltage.

Additional DC sources and switch circuits may be added to create additional multilevel pulses of any number of voltage levels.

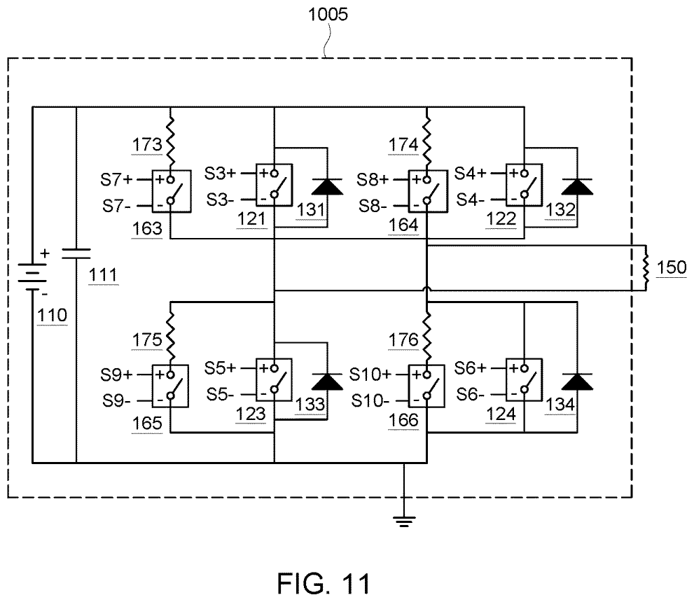

FIG. 11 shows an example high voltage bipolar pulsing power supply 1005 driving the load 150. In this example, the high voltage bipolar pulsing power supply 105 includes four tail sweeper switches (e.g., switches 163, 164, 165, 166) and corresponding tail sweeper resistors (e.g., resistors 173, 174, 175, and 176). Alternatively, the tail sweeper resistors can be replaced with inductors or capacitors.

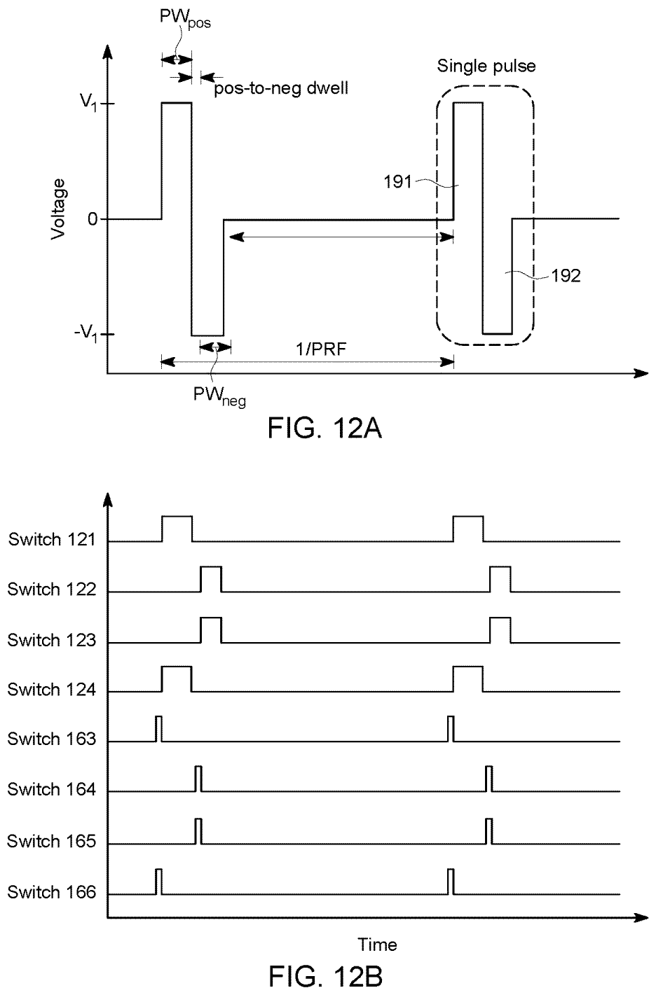

The first tail sweeper switch 163 and the first tail sweeper resistor 173 are coupled across the first switch circuit 121, the second tail sweeper switch 164 and the second tail sweeper resistor 174 are coupled across the second switch circuit 122, the third tail sweeper switch 165 and the third tail sweeper resistor 175 are coupled across the third switch circuit 123, and the fourth tail sweeper switch 166 and the fourth tail sweeper resistor 176 are coupled across the fourth switch circuit 124. Each tail sweeper switch can be closed prior to the corresponding switch circuit to dissipate any tail current in the circuit into the tail sweeper resistor as shown in FIG. 12B.

FIG. 12A shows bipolar pulses produced with the high voltage bipolar pulsing power supply 1005. FIG. 12B shows the shows the open and close switch logic of the switch circuits 121, 122, 123, 124, 125, and 126 and/or the tail sweeper switches 163, 164, 165, and 166 to produce the bipolar waveforms shown in FIG. 12A. For example, the tail sweeper switch 163 and the tail sweeper switch 166 are closed prior to closing the first switch circuit 121 and the fourth switch circuit 124. And the tail sweeper switch 164 and the tail sweeper switch 165 are closed prior to closing the second switch circuit 122 and the third switch circuit 123. By closing the tail sweeper switch 164 and the tail sweeper switch 165 prior to closing the second switch circuit 122 and the third switch circuit 123, the dwell between the positive pulse 191 and the negative pulse 192 can be substantially eliminated or completely eliminated.

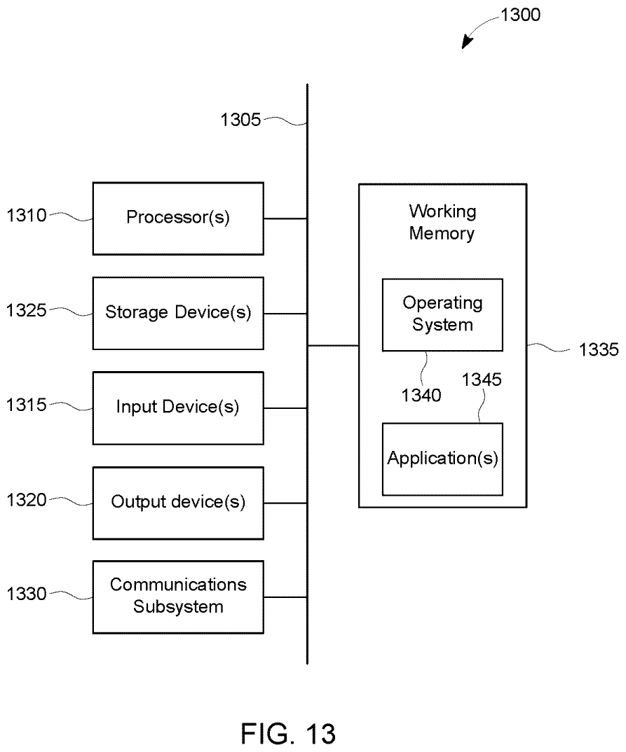

The computational system 1300, shown in FIG. 13 can be used to perform any of the examples disclosed in this document. For example, computational system 1300 can be used to control the switching of the various switch circuits described in this document. As another example, computational system 1300 can perform any calculation, identification and/or determination described here. The computational system 1300 may include hardware elements that can be electrically coupled via a bus 1305 (or may otherwise be in communication, as appropriate). The hardware elements can include one or more processors 1310, including without limitation one or more general-purpose processors and/or one or more special-purpose processors (such as digital signal processing chips, graphics acceleration chips, and/or the like); one or more input devices 1315, which can include without limitation a mouse, a keyboard and/or the like; and one or more output devices 1320, which can include without limitation a display device, a printer and/or the like.

The computational system 1300 may further include (and/or be in communication with) one or more storage devices 1325, which can include, without limitation, local and/or network accessible storage and/or can include, without limitation, a disk drive, a drive array, an optical storage device, a solid-state storage device, such as a random access memory (“RAM”) and/or a read-only memory (“ROM”), which can be programmable, flash-updateable and/or the like. The computational system 1300 might also include a communications subsystem 1330, which can include without limitation a modem, a network card (wireless or wired), an infrared communication device, a wireless communication device and/or chipset (such as a Bluetooth device, an 802.6 device, a Wi-Fi device, a WiMax device, cellular communication facilities, etc.), and/or the like. The communications subsystem 1330 may permit data to be exchanged with a network (such as the network described below, to name one example), and/or any other devices described in this document. In examples some examples, the computational system 1300 will further include a working memory 1335, which can include a RAM or ROM device, as described above.

The computational system 1300 also can include software elements, shown as being currently located within the working memory 1335, including an operating system 1340 and/or other code, such as one or more application programs 1345, which may include computer programs of the invention, and/or may be designed to implement methods of the invention and/or configure systems of the invention, as described herein. For example, one or more procedures described with respect to the method(s) discussed above might be implemented as code and/or instructions executable by a computer (and/or a processor within a computer). A set of these instructions and/or codes might be stored on a computer-readable storage medium, such as the storage device(s) 1325 described above.

In some cases, the storage medium might be incorporated within the computational system 1300 or in communication with the computational system 1300. In other examples, the storage medium might be separate from a computational system 1300 (e.g., a removable medium, such as a compact disc, etc.), and/or provided in an installation package, such that the storage medium can be used to program a general-purpose computer with the instructions/code stored thereon. These instructions might take the form of executable code, which is executable by the computational system 1300 and/or might take the form of source and/or installable code, which, upon compilation and/or installation on the computational system 1300 (e.g., using any of a variety of generally available compilers, installation programs, compression/decompression utilities, etc.) then takes the form of executable code.

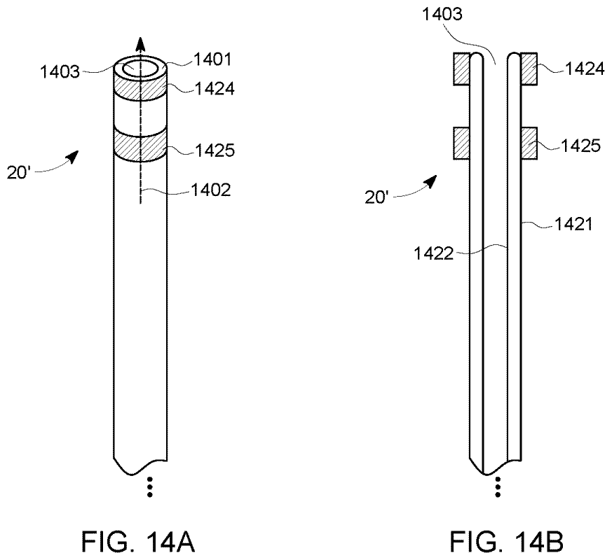

FIGS. 14A and 14B show a schematic of an alternative ablation catheter 20′ that may be used in system 10 of FIG. 1A. FIG. 14A shows a side view of an ablation catheter and FIG. 14B shows a cross-section view along a plane through the catheter's longitudinal axis 1402. Catheter 20′ is shown as having a central lumen 1403 inside a tubular element, and two electrodes on the outer surface 1421 of the tube: electrode 1424 is at or near the tip of the catheter at its distal end 1401, and electrode 1425 is located down the tube of the catheter away from the tip electrode. In FIGS. 14A and 14B, the electrodes are not attached to the inner surface 1422. When a voltage difference is applied between the two electrodes, they form a dipole. Tissue may be ablated by electroporation where the electric field directly induces cell damage.

Some ablation catheters have more than two electrodes on the outer surface 1421 of the catheter 20′. For cardiac applications for example, specialized multielectrode catheters can deliver electroporation to the ostium of pulmonary veins within the left atrium. Most of these devices are designed to perform anatomic ablation of the pulmonary veins to treat a common arrhythmia called atrial fibrillation.

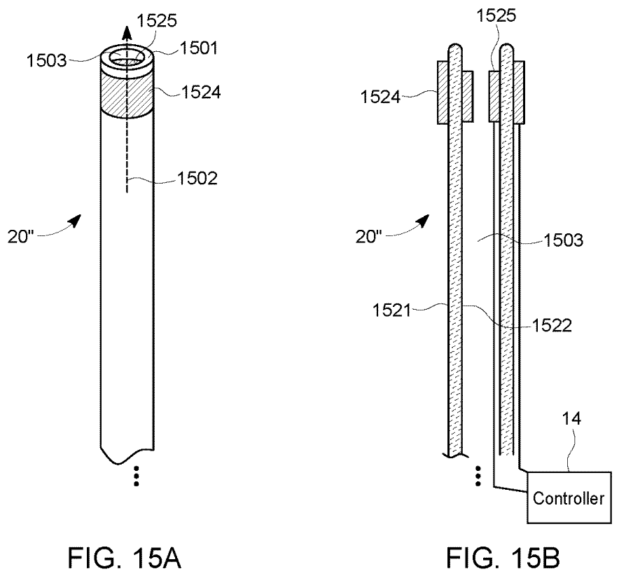

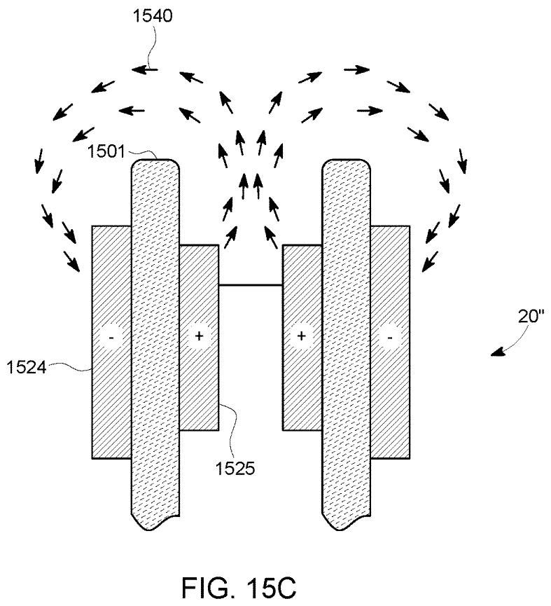

FIGS. 15A and 15B 2B depict an example of another alternative catheter 20″, which can be used in system 10 of FIG. 1A. Catheter 20″ has an outer electrode 1524 attached to the outer surface 1521 of the tubular catheter body, and an inner electrode 1525 attached to the inner surface 1522 (facing the lumen 1503) of the tubular catheter body. Both electrodes 1524 and 1525 are offset along the longitudinal axis 1502 from the distal end 1501 of the catheter; there is no electrode at the catheter tip. A distance between the outer electrode 1524 and the distal end 1501 may be at least 0.01 millimeters.

In applications, the distal end of the catheters 20, 20′, and 20″ may be placed at or near a tissue to be ablated. In the case of FIGS. 15A-15C, the outer electrode 1524 may be in contact with the tissue while inner electrode 1525 is not in direct contact with the tissue to be ablated. The electrodes may generate an electric field outside the tubular catheter body that induces ablation of nearby tissue via electroporation.

In some cases, lumen 1403 or 1503 of FIGS. 14A-15C of the catheter 20′ or 20″ may carry an irrigation fluid that is infused into the tissue; this fluid may be conductive. An illustrative fluid may be 9% normal saline, for example.

In some cases, inner electrode 1525 and outer electrode 1524 are separated by the distal portion of the catheter body, which may contain an electrically insulating material. In one or more examples the conductivity of this insulating material may be less than 0.1 micro-Siemens per centimeter, for example. In one or more examples this material may be a dielectric and it may have a high dielectric constant. An illustrative material that may be used in one or more examples may be aluminum nitride ceramic for example. (The portion of the catheter body below the electrodes (away from the distal end) may or may not be made of the same material as the portion of the body between the electrodes.) All or a portion of the catheter body may be flexible. The tubular catheter body may be of any desired length.

Electrodes 1524 and 1525 may be coupled to a generator/controller 14 that may set the voltage of each electrode, as shown in FIG. 15B. (The wires connecting the controller to the electrode are shown schematically as separated from the catheter body for ease of illustration; in applications these wires may be integrated into or attached to the catheter body, for example.) Generator/controller 14 may deliver voltage pulses to the electrodes 1524 and 1525. The pulses may be for example monophasic pulses with a duration between 10 ns and 10 ms, <50% duty cycle, amplitude between 1 kV-10 kV, pulse repetition between 1 and 10,000 pulses/second, inclusive. In particular, in one or more examples of the invention the voltage applied between at least one inner electrode and at least one outer electrode may be greater than 5000 volts. However, any electric potential pattern could be used with this electrode configuration including but not limited to multiple duration rectangular pulses, biphasic rectangular or trapezoidal waves, sinusoidal bipolar, sinusoidal offset, asymmetric rectangular, asymmetric rectilinear, and/or any combination of arbitrary waveform or pulse pattern combination.

FIG. 15C illustrates a similar bending effect on the shape of the electric field generated when a voltage difference is applied between the electrodes. The electric field lines 1540 bend around the distal end of the catheter. The dielectric in the catheter body amplifies the field strength as it bends around the tip.

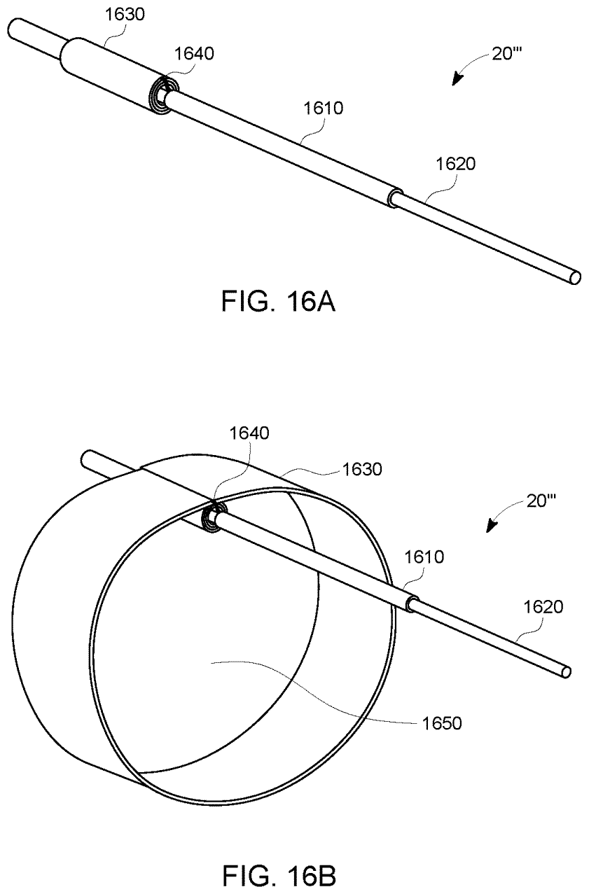

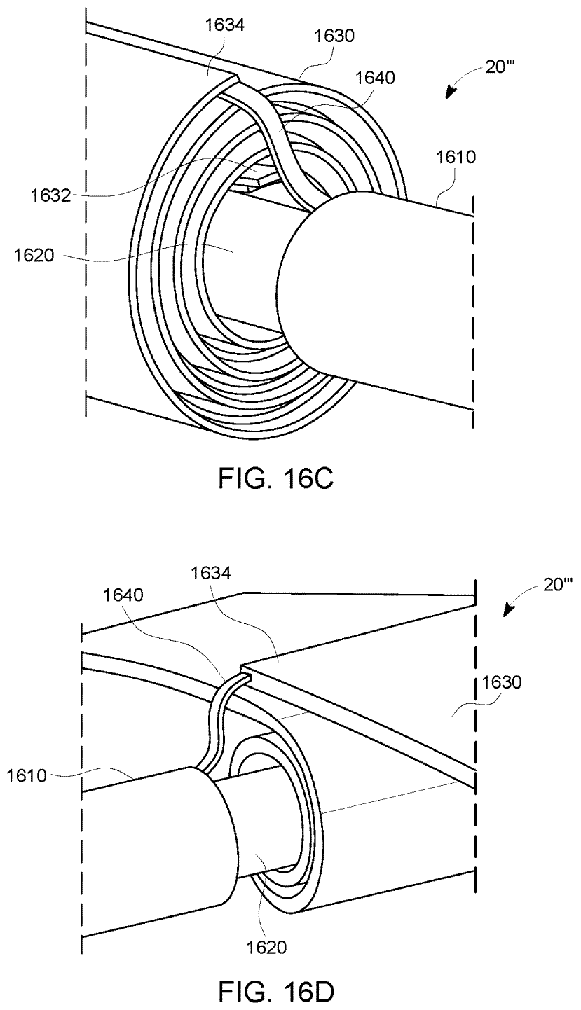

FIG. 16A is a perspective view of another embodiment of a pulsed electric field device 20′″. As depicted there, pulsed electric field device 20′″ may include a first elongate body 1610 comprising a lumen therethrough and a second elongate body 1620 at least partially positioned within the lumen of the first elongate body 1610. The pulsed electric field device 20′″ may further include an expandable member 1630, which may be rolled around (e.g., in mechanical contact with) the second elongate body 1620 about a longitudinal axis thereof. For example, as shown in FIGS. 16A-16D, the expandable member 1630 may include a plurality of turns about the second elongate body 1620 such that the expandable member 1630 forms a plurality (e.g., two, three, four, five, or more) layers wrapped around or rolled about the second elongate body 1620. That is, the expandable member 1630 may be in mechanical contact with the second elongate body 1620. In some cases, the expandable member 1630 (e.g., circuit substrate, flex circuit) may include an electrode array (not shown for the sake of clarity), which may include any of the electrode arrays described herein. For example, In some cases, the expandable member may be a flex circuit, while in other variations, the expandable member may include a base layer and a flex circuit may be coupled to the base layer. The electrode array may be disposed on an outer surface of the expandable member 1630. In some cases, a connector 1640 may couple the first elongate body 1610 to the expandable member 1630. For example, the connector 1640 may be configured to provide structural support to the expandable member 1630 such that at least a portion of the expandable member 1630 may be substantially fixed relative to the first elongate body 1610.

FIG. 16A depicts the pulsed electric field device 20′″ with the expandable member 1630 in a compressed or rolled configuration configured for advancement through one or more body cavities. When in the compressed or rolled configuration, the expandable member 1630 may have a generally cylindrical shape with a first inner diameter (e.g., lumen diameter) and a first outer diameter. FIG. 16B depicts the pulsed electric field device 20′″ with the expandable member 1630 in an expanded or unrolled configuration configured for engagement with tissue such as an inner surface of a duodenum (not shown for the sake of clarity). When in the expanded or unrolled configuration, the expandable member 1630 may have a generally elliptic or cylindrical shape with a second inner diameter and a second outer diameter having a predetermined larger than a respective first inner diameter and first outer diameter. The expandable member in the expanded configuration may have a predetermined flexibility configured to conform to a shape of the tissue to which it is engaged.

In some cases, the first and second elongate bodies 1610, 1620 may be configured to axially rotate relative to one another to transition the expandable member 1630 between the compressed configuration, the expanded configuration, and the semi-expanded configuration therebetween. For example, the second elongate body 1620 (e.g., inner torsion member, rotatable member) may be rotatably positioned within a lumen of the first elongate body 1610, such that rotation of the second elongate body 1620 relative to the first elongate body 1610 may transition the expandable member 1630 between a rolled configuration and an unrolled configuration. In some of these variations, the inner diameter of the lumen 1650 of the expandable member 1630 may be at least about 8 mm in the unrolled configuration, at least about 10 mm, or from about 8 mm to about 10 mm, including all values and sub-ranges in-between. As described in more detail herein, a visualization device (not shown) may be disposed within the lumen 1650 of the expandable member 1630 to aid in visualization. It should be appreciated that the pulsed electric field device 20′″ may be advanced next to a visualization device and/or over a guidewire. In some cases, a visualization device may be used to guide advancement and to visualize a treatment procedure such that a guidewire and/or other visualization modalities (e.g., fluoroscopy) are not needed.

In some cases, the expandable member 1630 may be configured to transition to a configuration between the compressed and expanded configurations. For example, the expandable member 1630 may transition to a partially or semi-expanded configuration (between the compressed configuration and expanded configuration) that may allow a visualization device (e.g., endoscope) to be disposed within a lumen of the expandable member 1630. In some cases, an inner surface of the expandable member may engage and hold a visualization device in a semi-expanded configuration.

As shown in the detailed perspective views of FIGS. 16C and 16D, the expandable member 1630 may include an inner end 1632 (e.g., innermost portion of roll) and an outer end 1634 (e.g., outermost portion of roll). FIG. 16C depicts the expandable member 1630 in the compressed configuration and FIG. 16D depicts the expandable member 1630 in the expanded configuration. In some cases, the inner end 1632 may be coupled to the second elongate body (e.g., attached to an external surface thereof) 1620 and the outer end 1634 may be coupled to the first elongate body 1610 (e.g., an external surface thereof). Coupling the ends of the expandable member 1630 to the first and second elongate bodies 1610, 1620 in this way allows for better control over the size and shape of the expandable member 1630. For example, an edge of the inner end 1632 substantially parallel to a longitudinal axis of the second elongate body 1620 may be attached to an outer surface of the second elongate body 1620 such that the inner end 1632 rotates with the rotation of the second elongate body 1620. A direction of the rotation (e.g., clockwise, counter-clockwise) of the second elongate body 1620 may determine the configuration (e.g., expansion or compression) of the expandable member 1630. For example, rotating the second elongate body 1620 in a clockwise direction relative to the first elongate body 1610 may expand or unroll the expandable member 1630, while rotating the second elongate body 1620 in a counterclockwise direction relative to the first elongate body 1610 may compress or roll the expandable member, or vice versa.

In some cases, a connector 1640 may couple the first elongate body 1610 to the outer end 1634 of the expandable member 1630, which may allow the expandable member 1630 to expand and compress while maintaining its relative position to the first elongate body 1610. In some cases, the connector may function as a torsional control arm between the expandable member 1630 and the first elongate body 1610. In some cases, the connector 1640 may include a curved shape such as an “S” shape, or may be straight (linear). The configurations shown in FIGS. 16C and 16D minimize the size of the connector 1640 to facilitate advancement of the device 20′″ in the compressed configuration by reducing a diameter of the compressed device 20′″.

In some cases, an electrode array may be electrically coupled to the first elongate body 1610 through the connector 1640. For example, one or more leads may be coupled to the electrode array through a lumen of the first elongate body 1610 and a lumen of the connector 1640. Additionally or alternatively, one or more leads may be coupled to the electrode array through a lumen of the second elongate body 1620. In some cases, the connector 1640 may be composed of a rigid or semi-rigid material or combination thereof such that the position of the outer end 1634 relative to the first elongate body 1610 remains substantially the same between a compressed configuration and an expanded configuration. Additionally or alternatively, the expandable members described herein may include a bimetallic strip configured to expand and compress through ohmic heating.

In some cases, the system with the distal end 20′″ can be used to treat tissue in the intestines. It may be helpful to briefly identify and describe the relevant intestine anatomy. The intestines can be accessed with devices provided herein by advancing such devices through the mouth, down the throat, through the esophagus, into the stomach, and to the duodenum. The duodenum surrounds the head of the pancreas and is a “C” shaped hollow jointed tube structure that is typically between about 20 cm and about 35 cm in length and about 20 mm and about 45 mm in diameter. The small intestine include the following layers, the mucosa, the submucosa, muscularis externa, and the serosa. Treatment of the duodenum may include resurfacing the mucosa as described herein. Access to the duodenum may be performed by advancing the systems and devices described herein through one or more of the esophagus, stomach, pylorus, lower esophageal junction, crackle pharyngeal junction, and several acute small radius bends throughout the length of the digestive tract.

Devices, systems, and methods herein can be used to provide suitable high voltage bipolar pulses to electrodes for electroporation. Electroporation is the application of an electric field to living cells to cause ions of opposite charge to accumulate on opposite sides of cell membranes. Generally, electroporation requires a potential difference across the cell membrane on the order of about 0.5 to about 1 volt and for a cumulative duration on the order of about 1 to about 2 milliseconds. Electroporation necessarily generates ohmic heating. The bulk tissue remains a good ionic conductor during the electroporation treatment, heating at a rate on an order of magnitude of about 800° C./s while the external field is being applied. If the external field is removed, the cell membranes may discharge on the order of about 30 nanoseconds, obliging the continued application of external voltage and current to induce pore formation and growth. As the maximum tolerable temperature rise of the bulk tissue may be on the order of about 13° C., the maximum duration that the external field may be applied, even in a bipolar configuration, may be within an order of magnitude of about 10 milliseconds. As this heat is generated to a treatment depth in the tissue of about several millimeters, the required time to cool the tissue by conduction may be about 70 seconds (e.g., (3 mm²)/(0.13 mm²/sec)). Blood convection likely dominates the observed cooling times that are on the order of about 10 seconds. Electroporation may also increase with the temperature of the bulk tissue due to the phase transition of the lipid cell membrane, which for some cells on the duodenum is 41° C. The phase transition temperature may be the temperature required to induce a change in the lipid physical state from the ordered gel phase to the liquid crystalline phase. Electroporation parameters may be varied to produce different effects on tissue. Electroporation with devices, systems and methods provided herein can reduce trauma to tissues surrounding the treatment area relative to the thermal treatments.

In some cases, a pulsed electric field (PEF) treatment using methods, devices, and systems provided herein may be combined with localized thermal treatment. For example, thermal treatment may be applied to surface tissue or near-surface tissue while PEF treatment may be applied to relatively deeper tissue. As described in more detail herein, the depth of tissue treatment received by one or more layers may be adjusted based on one or more of electrode design, applied voltage, time or duration of energy delivery, frequency of applied energy, and tissue configuration. An example of such control is thermal treatment applied up to a tissue depth of about 0.1 mm and a PEF treatment applied to a tissue depth of up to about 1 mm. The ratio and depth of thermal treatment to PEF treatment may be based on a desired clinical outcome (e.g., effect). In some cases, thermal treatment may be applied up to a tissue depth of about 3 mm, and PEF treatment may be applied up to a tissue depth of about 5 mm. Therefore, In some cases, more thermal treatment than PEF treatment may be applied to tissue. Based on a depth or type of tissue, different healing cascades maybe optimal. In some cases, the villas mucosa at up to about 1 mm may be thermally treated to allow substantially the entire tissue architecture to be replaced, while the submucosa may be PEF treated to preserve the tissue architecture and promote rapid healing of that layer. Furthermore, neither the thermal treatment nor PEF treatment may affect the deeper muscularis propria layer.

In some cases, methods, systems, and devices provided herein can be used as a treatment for diabetes, which can include treating the submucosa layer of the duodenum without substantially treating (or damaging) the muscularis. Conventional solutions do not consistently treat the submucosa layer without negatively impacting the muscularis. For reference, the mucosal layer typically has a thickness between about 0.5 mm to about 1 mm, the submucosa layer typically has a thickness of about 0.5 mm and about 1 mm, and the muscularis typically has a thickness of about 0.5 mm. Inducing injury to the muscularis may result in adverse clinical outcomes. Furthermore, the anatomical structure along a circumference of the duodenum is not uniform, thus complicating efforts to treat just the submucosa and not the muscularis. Methods provided herein may selectively change tissue viability without losing the integrity of the majority of the treated tissue in the duodenum by applying a predetermined pulsed or modulated electric field and, optionally, without other treatment of the tissue to mitigate the pulsed or modulated electric field to a portion of tissue. By contrast, RF based energy treatment may predominantly generate heat-induced cell lysis (e.g., cell death) or ablation that may indiscriminately damage tissue and destroy cellular structure, and which may be difficult to modulate, thus negatively impacting treatment outcomes. In some cases, the methods described here may include applying a pulsed or modulated electric field to thermally-induce local necrotic cell death (e.g., local ablation) for duodenal tissue immediately adjacent to an electrode array and to induce cell lysis (e.g., functional cell death) within a predetermined range of depths of duodenal tissue (e.g., up to about 1 mm, between about 0.5 mm and 0.9 mm) while minimizing the physiological impact to tissue greater than the selected depth. The pulsed or modulated electric fields near an electrode array may generate some thermal heating of tissue leading to tissue ablation that destroys both cell structure and function. However, cell lysis in tissue resulting from the pulsed or modulated electric fields applied herein are at least 50% pore-induced and less than 50% heat-induced such that a majority of cell death includes functional cell death with intact cellular structures. For example, the thermal heating generated by a pulsed or modulated electric field is generally localized to a relatively small radius from each electrode of an electrode array and does not affect deeper layers of tissue such as the muscularis.

Systems, devices, and methods provided herein can deliver energy to provide treatment characteristics optimized for each tissue layer to improve treatment outcomes. Near the surface of the tissue (e.g., less than about 0.5 mm, between about 0.1 mm and about 0.5 mm), thermal heating may generate local necrotic cell death of tissue that may slough off after treatment. At a tissue depth of between about 0.5 mm and about 1.3 mm (e.g., mucosa of duodenum), cell lysis may be generated by the pulsed or modulated electric field while thermal heating is limited (e.g., to less than about a 13° C. increase or 6° C. increase). For example, an electric field strength at about 1.0 mm may be about 2.5 kV/cm. At tissue depths beyond 1.0 mm, the energy delivered to tissue generates reversible electroporation with even less thermal heating such that deeper tissue may be substantially untreated. Thus, thermal heating may be limited to a surface tissue layer (e.g., less than about 0.5 mm, between about 0.1 mm and about 0.5 mm) while still delivering pulsed or modulated electric field energy for cell lysis of the mucosa.

In some cases, pulsed electric field (PEF) treatment may be applied while monitoring and/or minimizing tissue temperature increases. For example, a predetermined rise in tissue temperature (e.g., about 1° C., about 2° C., about 3° C.) may be followed by a pause (e.g., of a predetermined time interval) in energy delivery to allow the tissue to cool. In this manner, the total energy delivered may increase the tissue temperature below a predetermined threshold (e.g., below a safety limit). In some cases, the predetermined threshold may be up to about 3° C., about 6° C., about 10° C., about 13° C., including all ranges and sub-values in-between. In some cases, the tissue power densities generated by a pulsed or modulated electric field devices provided herein may be driven at greater than about 50 Vᵣₘₛ, greater than about 100 Vᵣₘₛ, greater than about 200 Vᵣₘₛ, greater than about 300 Vᵣₘₛ, greater than about 400 Vᵣₘₛ, greater than about 500 Vᵣₘₛ, or greater than about 600 Vᵣₘₛ.

Also described herein are methods. In some cases, a method of treating duodenal tissue (i.e., as a diabetes treatment) may include advancing a pulsed electric field device toward a first portion of a duodenum of a patient. The pulsed electric field device may include an expandable member comprising an electrode array. The expandable member may be transitioned from a compressed configuration into an expanded configuration bringing the expandable member (and the electrode array) closer to or in contact with the inner surface of the duodenum. The expandable member may include a flexibility to apply force against and conform to an inner circumference of the duodenum that may itself include a range of diameters. A first pulse waveform may be delivered to the electrode array to generate a first pulsed or modulated electric field, which may treat the tissue in the first portion. The pulsed electric field device may be moved (e.g., advanced or retracted) toward a second portion of the duodenum (which may be distal or proximal to the first portion), and a second pulse waveform may be delivered to the electrode array to generate a second pulsed or modulated electric field thereby treating the tissue in the second portion. For example, In some cases, a signal generator may generate a drive voltage of between about 400 V and about 1500 V that may correspond to an electric field strength of about 400 V/cm and about 7000 V/cm at the treatment portions of the duodenum. The expandable member may be in a compressed configuration, semi-expanded configuration, and expanded configuration during movement of the pulsed electric field device. In some cases, a visualization device may be configured to visualize one or more of the pulsed electric field device and tissue. In some cases, temperature sensor measurements may be used to monitor and/or control pulse waveform delivery. In some cases, current and voltage measurements may be used to monitor and/or control pulse waveform delivery.

Unless otherwise specified, the term “substantially” means within 5% or 10% of the value referred to or within manufacturing tolerances. Unless otherwise specified, the term “about” means within 5% or 10% of the value referred to or within manufacturing tolerances.

The conjunction “or” is inclusive.

The terms “first”, “second”, “third”, etc. are used to distinguish respective elements and are not used to denote a particular order of those elements unless otherwise specified or order is explicitly described or required.

Numerous specific details are set forth to provide a thorough understanding of the claimed subject matter. However, those skilled in the art will understand that the claimed subject matter may be practiced without these specific details. In other instances, methods, apparatuses or systems that would be known by one of ordinary skill have not been described in detail so as not to obscure claimed subject matter.

While the present subject matter has been described in detail with respect to specific examples thereof, it will be appreciated that those skilled in the art, upon attaining an understanding of the foregoing, may readily produce alterations to, variations of, and equivalents to such examples. Accordingly, present disclosure has been presented for purposes of example rather than limitation, and does not preclude inclusion of such modifications, variations and/or additions to the present subject matter as would be readily apparent to one of ordinary skill in the art.

That which is claimed:

1. A bipolar high voltage treatment system comprising:
an electrode for ablation or electroporation; and
a power supply for supplying bipolar high voltage pulses to the electrode, the power supply comprising a DC Source, an energy storage capacitor coupled with the DC source, a first high voltage switch electrically coupled with the DC source and the energy storage capacitor, and a first diode arranged across arranged across the first high voltage switch.

2. The bipolar high voltage treatment system according to claim 1, wherein the power supply comprises a first tail sweeper switch and a first tail sweeper resistor arranged in series across the first high voltage switch.

3. The bipolar high voltage treatment system according to claim 1, wherein the power supply further comprises:
a second high voltage switch electrically coupled with the DC source and the energy storage capacitor; and
a second diode arranged across the second high voltage switch.

4. The bipolar high voltage treatment system according to claim 3, wherein the power supply further comprises a second tail sweeper switch and a second tail sweeper resistor arranged in series across the first high voltage switch.

5. The bipolar high voltage treatment system according to claim 3, wherein the power supply further comprises:
a third high voltage switch arranged in series between the first high voltage switch and ground; and
a third diode arranged across the third high voltage switch.

6. The bipolar high voltage treatment system according to claim 5, wherein the power supply further comprises a third tail sweeper switch and a third tail sweeper resistor arranged in series across the first high voltage switch.

7. The bipolar high voltage treatment system according to claim 5, wherein the power supply further comprises:
a fourth high voltage switch arranged in series between the second high voltage switch and ground; and
a fourth diode arranged across the fourth high voltage switch.

8. The bipolar high voltage treatment system according to claim 7, wherein the power supply further comprises a fourth tail sweeper switch and a fourth tail sweeper resistor arranged in series across the first high voltage switch.

9. The bipolar high voltage treatment system according to claim 7, wherein the power supply further comprises an output having a first lead electrically coupled between first high voltage switch and the third high voltage switch and the second lead electrically coupled between second high voltage switch and the fourth high voltage switch.

10. The bipolar high voltage treatment system according to claim 9, wherein the first high voltage switch comprises a first plurality of solid state switches arranged in parallel, the second high voltage switch comprises a second plurality of solid state switches arranged in parallel, the third high voltage switch comprises a third plurality of solid state switches arranged in parallel, and the fourth high voltage switch comprise a fourth plurality of solid state switches arranged in parallel.

11. The bipolar high voltage treatment system according to claim 9, wherein the first high voltage switch, the second high voltage switch, the third high voltage switch, and the fourth high voltage switch each comprise a switch selected from the group consisting of an IGBT, a MOSFET, a SiC MOSFET, a SiC junction transistor, a FET, a SiC switch, a GaN switch, and a photoconductive switch, wherein the circuit comprising both the DC source and the energy storage capacitor has an inductance less than about 10 nH, and wherein the circuit comprising both the first high voltage bipolar pulsing power supply and the second high voltage switch has an inductance less than about 10 nH.

12. The bipolar high voltage treatment system according to claim 1, wherein the power supply is adapted to produce high voltage bipolar pulses with a positive high voltage pulse greater than about 200 V followed by a negative high voltage pulse less than about −200 V.

13. The bipolar high voltage treatment system according to claim 12, wherein the power supply is adapted to produce high voltage bipolar pulses with a positive high voltage pulse greater than about 500 V followed by a negative high voltage pulse less than about −500 V.

14. The bipolar high voltage treatment system according to claim 1, wherein system applies high voltage pulses to an electrode for ablation treatment with a pulse repetition frequency greater than about 10 kHz.

15. The bipolar high voltage treatment system according to claim 1, wherein the power supply is adapted to deliver a pulsed waveform to the electrode to generate an electric field to treat tissue.

16. The bipolar high voltage treatment system according to claim 15, further comprising:
an elongate body; and
an expandable member comprising the electrode for ablation or electroporation, the expandable member being adapted to have a compressed configuration and an expanded configuration, wherein, in the expanded configuration, the expandable member is configured to dilate tissue;
wherein the power supply is adapted to deliver a pulsed waveform to the electrode to generate an electric field to treat the tissue.

17. The bipolar high voltage treatment system according to claim 16, wherein the expandable member further comprises a fluid opening, wherein the expandable member, while in the expanded configuration, is further adapted to apply suction to the tissue via the fluid opening.

18. The bipolar high voltage treatment system according to claim 16, wherein the expandable member comprises an array of electrodes, wherein the array of electrodes comprises the electrode for ablation or electroporation.

19. A bipolar high voltage tissue treatment system comprising:
a pulsed electric field device comprising:
an elongate body; and
an expandable member comprising a compressed configuration, an expanded configuration, an electrode for ablation or electroporation, and a fluid opening, wherein, in the expanded configuration, the expandable is configured to dilate tissue and to apply suction to the tissue via the fluid opening of the expandable member; and
a power supply configured to deliver a pulse waveform to the electrode to generate a pulsed or modulated electric field to treat the tissue, wherein the power supply is adapted to produce high voltage bipolar pulses with a positive high voltage pulse greater than about 200 V followed by a negative high voltage pulse less than about −200 V.

20. A bipolar high voltage treatment system comprising a power supply, the power supply comprising:
a first DC source;
a first energy storage capacitor coupled with the first DC source;
a first diode having an anode and a cathode, the anode electrically coupled with the first DC source and the first energy storage capacitor;
a first high voltage switch electrically coupled with the cathode of the first diode;
a first diode arranged across the first high voltage switch;
a second high voltage switch electrically coupled with the cathode of the first diode;
a second diode arranged across the second high voltage switch;
a third high voltage switch arranged in series between the first high voltage switch and ground;
a third diode arranged across the third high voltage switch;
a fourth high voltage switch arranged in series between the second high voltage switch and ground;
a fourth diode arranged across the fourth high voltage switch;
a second DC source;
a second energy storage capacitor coupled with the second DC source;
a fifth high voltage switch electrically coupled with the second DC source and the second energy storage capacitor;
a fifth diode arranged across the fifth high voltage switch;
a sixth high voltage switch electrically coupled with the cathode of the second DC source and the second energy storage capacitor;
a sixth diode arranged across the sixth high voltage switch; and
an output having a first lead electrically coupled between first high voltage switch and the third high voltage switch and the second lead electrically coupled between second high voltage switch and the fourth high voltage switch.
